(19) United States
(12) Patent Application Publication
(10) Pub. No.: US 2025/0376753 A1
(43) Pub. Date: Dec. 11, 2025

(54) MASK ASSEMBLY AND METHOD OF MANUFACTURING MASK ASSEMBLY

(71) Applicant: Samsung Display Co., LTD., Yongin-si (KR)

(72) Inventors: Sungwon CHO, Yongin-si (KR); Jeongkuk KIM, Yongin-si (KR); Junho JO, Yongin-si (KR); Yehwan CHOI, Yongin-si (KR)

(21) Appl. No.: 19/059,537

(22) Filed: Feb. 21, 2025

(30) Foreign Application Priority Data
Jun. 7, 2024 (KR) 10-2024-0074574

(51) Int. Cl. C23C 14/04; H10K 71/16

(52) U.S. Cl. CPC C23C 14/042; H10K 71/166

(57) ABSTRACT

Provided are a mask assembly and a method of manufacturing the mask assembly. The mask assembly includes a mask frame including an opening area, a body unit disposed which covers the mask frame and includes ribs that cross the opening area, intersect one another, and define a first opening, and a mask sheet disposed on a first surface of the body unit and having a sheet unit that defines a plurality of second openings overlapping the first opening. The sheet unit includes a first film disposed on the first surface of the body unit and a second film disposed on the first film to overlap the first film. A width of the first film between adjacent second openings from among the plurality of second openings is less than a width of the second film between the adjacent second openings.

This application claims priority to Korean Patent Application No. 10-2024-0074574, filed on Jun. 7, 2024, and all the benefits accruing therefrom under 35 U.S.C. § 119, the content of which in its entirety is herein incorporated by reference.

### BACKGROUND

### 1. Field

One or more embodiments relate to a mask assembly and a method of manufacturing a mask assembly, and more particularly, to a mask assembly in which deposition quality may be improved, and a method of manufacturing the mask assembly.

### 2. Description of the Related Art

Recently, electronic devices have been widely used. Various electronic devices, such as mobile electronic devices and fixed electronic devices, have been used, and such electronic devices include display devices capable of providing the user with visual information such as images or videos, to support various functions.

Display devices visually display data and may be formed by depositing various layers such as an organic layer, an inorganic layer, and a metal layer. In order to form a plurality of layers of a display device, a deposition material may be deposited. In other words, a deposition material may be sprayed from a deposition source and may be deposited on a display substrate through a mask assembly.

In some cases, the deposition quality may be enhanced by preventing a shadow phenomenon of the deposition material deposited on the display substrate through the mask assembly.

The related art described herein is technical information that the inventor possessed for deriving the disclosure or acquired during the process of deriving the disclosure and cannot necessarily be considered as publicly known technology disclosed to the general public prior to the application of the disclosure.

### SUMMARY

One or more embodiments include a mask assembly in which deposition quality may be improved, and a method of manufacturing the mask assembly.

However, these objectives are examples, and the objectives of the disclosure are not limited thereto.

Additional aspects will be set forth in part in the description which follows and, in part, will be apparent from the description, or may be learned by practice of the presented embodiments of the disclosure.

According to one or more embodiments, a mask assembly includes a mask frame including an opening area, and a body unit disposed such that the body unit covers the mask frame, wherein the body unit includes ribs that cross the opening area, intersect one another, and define a first opening, and a mask sheet disposed on a first surface of the body unit and having a sheet unit that defines a plurality of second openings overlapping the first opening, wherein the sheet unit includes a first film and a second film, wherein the first film is disposed on the first surface of the body unit, and the second film is disposed on the first film and overlaps the first film, and a width of the first film between adjacent second openings from among the plurality of second openings is less than a width of the second film between the adjacent second openings.

In an embodiment, the sheet unit may be disposed such that the sheet unit surrounds an outer periphery of the body unit.

In an embodiment, the first film and the second film may be disposed on a second surface of the body unit, the second surface facing the first surface of the body unit.

In an embodiment, the first film may include silicon oxide and the second film may include silicon nitride.

In an embodiment, the first film and the second film may include silicon nitride.

In an embodiment, the silicon nitride may include silicon nitride (Si₃N₄).

In an embodiment, a density of the silicon nitride may be about 2.9 g/cm³ to about 3.1 g/cm³.

In an embodiment, tensile stress of the silicon nitride may be about 50 MPa to about 300 MPa.

In an embodiment, the sheet unit may further include a third film, wherein the third film is disposed on the second film and overlapping the second film, and the width of the second film between the adjacent second openings may be less than a width of the third film between the adjacent second openings.

In an embodiment, the first film, the second film, and the third film may be disposed on a second surface of the body unit, the second surface facing the first surface of the body unit.

In an embodiment, the first film may include silicon nitride, the second film may include silicon oxide, and the third film may include silicon nitride.

According to one or more embodiments, a method of manufacturing a mask assembly includes preparing a body unit, the body unit including a silicon material and having a first surface and a second surface facing the first surface, forming a first film by oxidizing an entire surface of the body unit, disposing an alignment key on the first film, forming a second film which surrounds an entire surface of the first film, etching first portions of the first film and the second film, wherein the first portions are disposed on a second film of the body unit, forming a first opening by etching the body unit through the second surface of the body unit, wherein the etching exposes the second surface, and etching second portions of the first film and the second film and forming a plurality of second openings that overlap the first opening, wherein the second portions are exposed through the first opening.

In an embodiment, a width of the first film between adjacent second openings from among the plurality of second openings may be less than a width of the second film between the adjacent second openings.

In an embodiment, etching the body unit may include wet etching the body unit, and the first film may function as a stopper layer to stop the etching.

In an embodiment, the etching of the second portions of the first film and the second film may include attaching a protective layer onto the second film.

In an embodiment, the etching of the second portions of the first film and the second film may include disposing a photoresist on an inner surface of the first film, and the inner surface may be exposed through the first opening.

In an embodiment, the first portions of the first film and the second film may be etched by dry etching.

In an embodiment, the first film may include silicon oxide and the second film may include silicon nitride.

In an embodiment, the first film and the second film may include silicon nitride.

According to one or more embodiments, a method of manufacturing a mask assembly includes preparing a body unit, the body unit including a silicon material and having a first surface and a second surface facing the first surface, forming a first film which surrounds an entire surface of the body unit, forming a plurality of first sub-openings by etching part of the first film, forming a second film by oxidizing an entire surface of the first film, to surround the entire surface of the first film, forming a third film to surround an entire surface of the second film, forming a plurality of third sub-openings overlapping the plurality of first sub-openings by etching part of the third film, etching portions of the first film, the second film, and the third film, wherein the portions of the first film, the second film, and the third film are disposed on the second surface of the body unit, forming a first opening by etching the body unit through the second surface of the body unit, wherein the etching exposes the second surface, and the second film is exposed through the first opening, and forming a plurality of second sub-openings overlapping the plurality of first sub-openings by etching the second film exposed through the first opening, wherein the forming of the plurality of first sub-openings, the plurality of second sub-openings, and the plurality of third sub-openings defines a second opening.

Other aspects, features and advantages other than those described herein will become apparent from the following detailed description, claims, and drawings for practicing the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view illustrating a manufacturing device for a display device according to an embodiment;

FIG. 2 is a plan view schematically illustrating a mask assembly according to an embodiment;

FIG. 3 is an enlarged view of region III of FIG. 2;

FIG. 4 is a cross-sectional view schematically illustrating a mask assembly according to an embodiment, taken along line IV-IV′ of FIG. 3;

FIG. 5 is a cross-sectional view schematically illustrating a mask assembly according to an embodiment, similar to FIG. 4;

FIG. 6 is a cross-sectional view schematically illustrating a mask assembly according to an embodiment, similar to FIG. 4;

FIGS. 7 to 15 are diagrams schematically illustrating a method of manufacturing a mask assembly, according to an embodiment;

FIGS. 16 to 24 are diagrams schematically illustrating a method of manufacturing a mask assembly, according to an embodiment;

FIG. 25 is a perspective view schematically illustrating a display device manufactured by using a manufacturing device for a display device, according to an embodiment;

FIG. 26 is an equivalent circuit diagram of one pixel circuit included in a display device, the display device being manufactured by using a manufacturing device for a display device, according to an embodiment; and

FIG. 27 is a cross-sectional view schematically illustrating a display device manufactured by using a manufacturing device for a display device, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are described herein, by referring to the figures, to explain example aspects of the present description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

As the disclosure allows for various changes and numerous embodiments, certain embodiments will be illustrated in the drawings and described in detail in the written description. Hereinafter, effects and features of the present disclosure and a method for accomplishing them will be described more fully with reference to the accompanying drawings, in which embodiments of the disclosure are illustrated. This disclosure may, however, be embodied in many different forms and should not be construed as limited to the embodiments set forth herein.

One or more embodiments will be described herein in more detail with reference to the accompanying drawings. Those components that are the same or are in correspondence are rendered the same reference numeral regardless of the figure number, and redundant descriptions thereof are omitted.

In an embodiment below, terms such as, for example, “first” and “second” are used herein merely to describe a variety of elements, but the elements are not limited by the terms. Such terms are used only for the purpose of distinguishing one element from another element.

In an embodiment below, an expression used in the singular encompasses the expression of the plural, unless it has a clearly different meaning in the context.

In an embodiment below, terms such as, for example, “include” or “comprise” may be construed to denote a certain characteristic or element, or a combination thereof, but may not be construed to exclude the existence of or a possibility of addition of one or more other characteristics, elements, or combinations thereof.

It will be understood that when a layer, region, or element is referred to as being “formed on” another layer, region, or element, it can be directly or indirectly formed on the other layer, region, or element. That is, for example, intervening layers, regions, or elements may be present.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ±30%, 20%, 10%, 5% of the stated value, for example.

The term “substantially,” as used herein, means approximately or actually. The term “substantially equal” means approximately or actually equal. The term “substantially the same” means approximately or actually the same. The term “substantially flat” means approximately or actually flat.

Sizes of elements in the drawings may be exaggerated or reduced for convenience of explanation. In other words, since sizes and thicknesses of components in the drawings are arbitrarily illustrated for convenience of explanation, the following embodiments are not limited thereto.

In the following embodiments, the x-axis, the y-axis, and the z-axis are not limited to three axes of the rectangular coordinate system, and the x-axis, the y-axis, and the z-axis may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

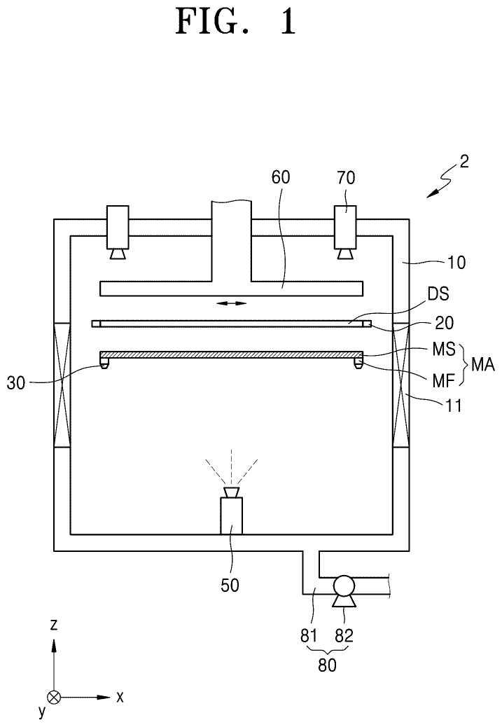

FIG. 1 is a cross-sectional view illustrating a manufacturing device 2 for a display device according to an embodiment.

The manufacturing device 2 for a display device may include a chamber 10, a first support unit 20, a second support unit 30, a mask assembly MA, a deposition source 50, a magnetic force unit 60, a vision unit 70, and a pressure control unit 80.

The chamber 10 may have a space formed therein, and the chamber 10 may store a display substrate DS and the mask assembly MA. In this case, a portion of the chamber 10 may be formed to be opened, and a gate valve 11 may be installed in the opened portion of the chamber 10. In this case, the opening portion of the chamber 10 may be opened or closed according to an operation of the gate valve 11.

In this case, the display substrate DS may refer to the display substrate DS being manufactured of the display device, obtained by depositing at least one of an organic layer, an inorganic layer, and a metal layer on a substrate 100, which is described herein. Alternatively, the display substrate DS may be the substrate 100 on which none of an organic layer, an inorganic layer, and a metal layer are deposited yet.

The first support unit 20 may support the display substrate DS. In this case, the first support unit 20 may be in a shape of a plate fixed inside the chamber 10. In another embodiment, the first support unit 20 may have the display substrate DS mounted thereon, and the first support unit 20 may be in a shape of a shuttle capable of linearly moving within the chamber 10. In another embodiment, the first support unit 20 may include an electrostatic chuck or adhesive chuck that is fixed to the chamber 10 or positioned in the chamber 10 to be movable within the chamber 10.

The second support unit 30 may support the mask assembly MA. In this case, the second support unit 30 may be arranged inside the chamber 10. The second support unit 30 may finely adjust a position of the mask assembly MA. In this case, the second support unit 30 may have a separate driving unit or alignment unit to enable the mask assembly MA to move in different directions.

In another embodiment, the second support unit 30 may be in a shape of a shuttle. In this case, the second support unit 30 may have the mask assembly MA mounted thereon and may transport the mask assembly MA. For example, the second support unit 30 may move out of the chamber 10, and after the mask assembly MA is mounted on the second support unit 30, enter the chamber 10 from the outside of the chamber 10.

In this case, the first support unit 20 and the second support unit 30 may be integrally formed as a single body. In this case, the first support unit 20 and the second support unit 30 may include a movable shuttle. In this case, the first support unit 20 and the second support unit 30 may include a structure for fixing the mask assembly MA and the display substrate DS while the display substrate DS is mounted on the mask assembly MA, and the display substrate DS and the mask assembly MA may linearly move simultaneously.

However, hereinbelow, for convenience of description, a shape in which the first support unit 20 and the second support unit 30 are formed to be distinguished from each other and are arranged in different positions, and the first support unit 20 and the second support unit 30 are arranged inside the chamber 10 is mainly described in detail.

The deposition source 50 may be arranged to face the mask assembly MA. In this case, the deposition source 50 may store a deposition material, and the deposition material may be evaporated or sublimated by applying heat to the deposition material. The deposition source 50 may be arranged such that the deposition source 50 is fixed inside the chamber 10, or the deposition source 50 may be arranged within the chamber 10 and be linearly moveable in one or more directions.

The mask assembly MA may be arranged inside the chamber 10. In this case, the mask assembly MA may include a mask frame MF and a mask sheet MS. This is described herein in detail. A deposition material may pass through the mask assembly MA and may be deposited on the display substrate DS.

The magnetic force unit 60 may be arranged within the chamber 10 to face the display substrate DS and/or the mask assembly MA. In this case, the magnetic force unit 60 may apply a magnetic force to the mask assembly MA and force the mask assembly MA toward the display substrate DS. In particular, the magnetic force unit 60 may not only prevent the mask sheet MS from sagging, but may also allow the mask sheet MS to be adjacent to the display substrate DS. In some aspects, the magnetic force unit 60 may maintain a uniform gap between the mask sheet MS and the display substrate DS.

The vision unit 70 is arranged in the chamber 10 and may photograph positions of the display substrate DS and the mask assembly MA. In this case, the vision unit 70 may include a camera for photographing the display substrate DS and the mask assembly MA. Based on images captured in the vision unit 70, the positions of the display substrate DS and the mask assembly MA may be identified, and deformation of the mask assembly MA may be identified. In some aspects, based on the image, the position of the display substrate DS on the first support unit 20 may be finely adjusted, or the position of the mask assembly MA on the second support unit 30 may be finally adjusted. However, hereinbelow, a case in which the positions of the display substrate DS and the mask assembly MA are aligned by finely adjusting the position of the mask assembly MA on the second support unit 30 is mainly described in detail.

The pressure control unit 80 may be connected to the chamber 10 and may control pressure inside the chamber 10. For example, the pressure control unit 80 may control the pressure inside the chamber 10 to be equal to or similar to the atmospheric pressure. In some aspects, the pressure control unit 80 may control the pressure inside the chamber 10 to be equal to or similar to a vacuum state.

The pressure control unit 80 may include a connection pipe 81, connected to the chamber 10, and a pump 82 installed on the connection pipe 81. In this case, depending on an operation of the pump 82, external air may be introduced through the connection pipe 81, or gas inside the chamber 10 may be guided to the outside through the connection pipe 81.

When a method of manufacturing a display device (not illustrated) by using the manufacturing device 2 for a display device described herein is discussed, the display substrate DS may first be prepared.

The pressure control unit 80 may maintain the inside of the chamber 10 at a pressure equal to or similar to the atmospheric pressure, and the gate valve 11 may operate and open the opened portion of the chamber 10.

Thereafter, the display substrate DS may be loaded into the chamber 10 from the outside of the chamber 10. In this case, the display substrate DS may be loaded into the chamber 10 in various ways. For example, the display substrate DS may be loaded into the chamber 10 from the outside of the chamber 10 through a robot arm or the like arranged outside the chamber 10. In another embodiment, when the first support unit 20 is formed in a shape of a shuttle, after the first support unit 20 is moved out of the chamber 10 from the inside the chamber 10, the display substrate DS may be mounted on the first support unit 20 through a separate robot arm or the like arranged outside the chamber 10, and the first support unit 20 may be loaded into the chamber 10 from the outside of the chamber 10.

The mask assembly MA may be arranged inside the chamber 10 as described herein. In another embodiment, the mask assembly MA may be loaded into the chamber 10 from the outside of the chamber 10, in the same or similar manner as the display substrate DS.

When the display substrate DS is loaded into the chamber 10, the display substrate DS may be mounted on the first support unit 20. In this case, the vision unit 70 may photograph the positions of the display substrate DS and the mask assembly MA. The positions of the display substrate DS and the mask assembly MA may be identified based on the image captured in the vision unit 70. In this case, the manufacturing device 2 for a display device may have a separate control unit (not illustrated) to identify the positions of the display substrate DS and the mask assembly MA.

When the positions of the display substrate DS and the mask assembly MA have been identified, the second support unit 30 may finely adjust the position of the mask assembly MA.

Thereafter, the deposition source 50 may operate to supply a deposition material to the mask assembly MA, and the deposition material passing through a plurality of pattern holes of the mask sheet MS may be deposited on the display substrate DS. In this case, the deposition source 50 may move parallel to the display substrate DS and the mask assembly MA, or the display substrate DS and the mask assembly MA may move parallel to the deposition source 50. In other words, the deposition source 50 may move relative to the display substrate DS and the mask assembly MA. In this case, the pump 82 may maintain pressure inside the chamber 10 in a vacuum-like or similar form by sucking gas inside the chamber 10 and discharge the sucked air to the outside.

The deposition material supplied from the deposition source 50 as described herein may pass through the mask assembly MA and may be deposited on the display substrate DS, and the deposition material may accordingly form at least one of a plurality of layers, for example, an organic layer, an inorganic layer, and a metal layer, to be deposited in a display device described herein.

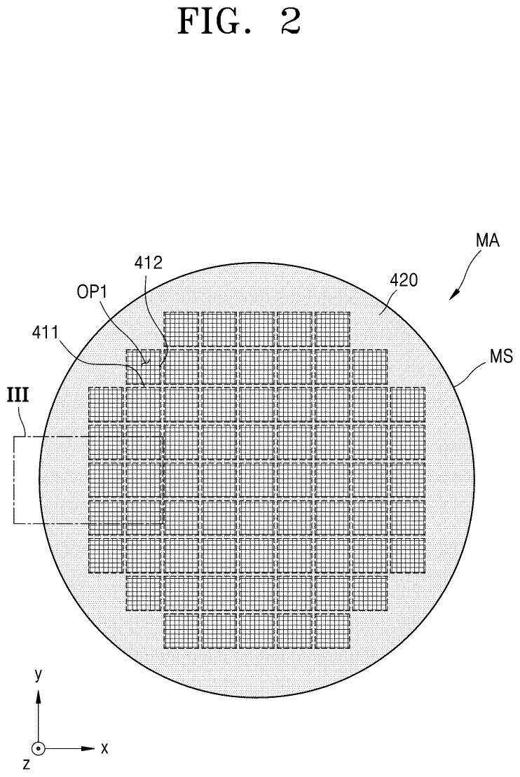

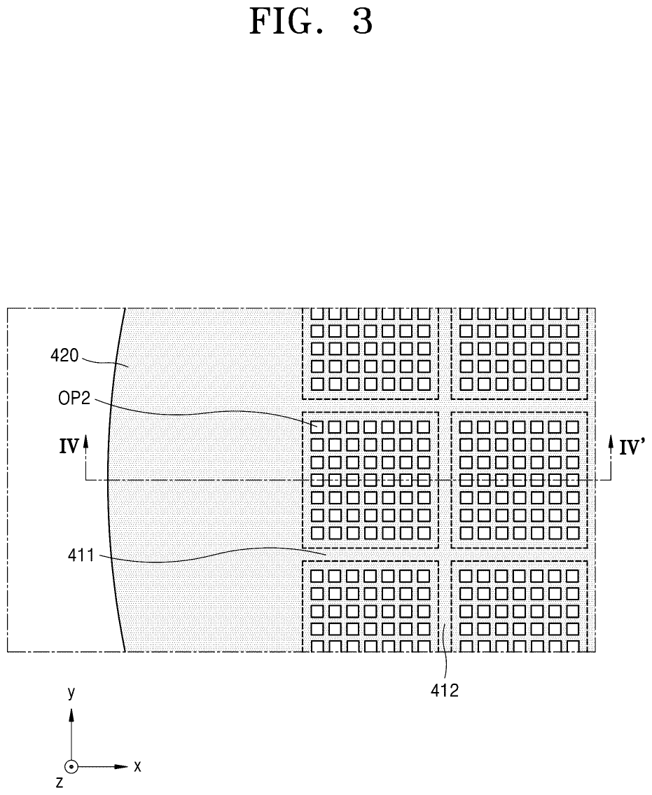

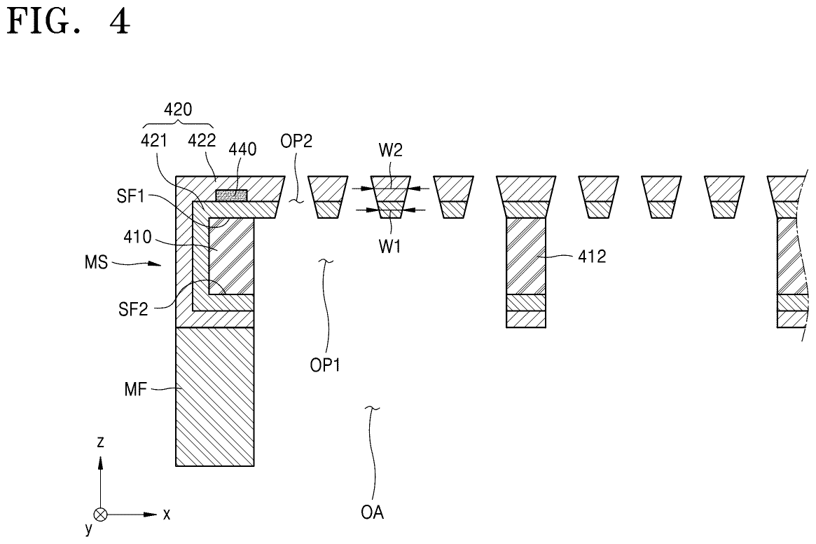

FIG. 2 is a plan view schematically illustrating the mask assembly MA according to an embodiment. FIG. 3 is an enlarged view of region III of FIG. 2. FIG. 4 is a cross-sectional view schematically illustrating a mask assembly according to an embodiment, taken along line IV-IV′ of FIG. 3.

Referring to FIGS. 2 to 4, the mask assembly MA may include the mask frame MF and the mask sheet MS.

The mask frame MF is a frame that supports the mask sheet MS, and the mask frame MF may define an opening area OA in the center of the mask sheet MS. In an embodiment, the mask frame MF may be a circular frame, and the opening area OA may be defined as circular. However, the shape of the mask frame MF is not limited thereto and may be various polygonal shapes. Hereinbelow, for convenience of description, a case in which the mask frame MF is a circular frame is mainly described.

The mask sheet MS may be installed on the mask frame MF. The opening area OA in the center of the mask frame MF may be covered by the mask sheet MS. In an embodiment, the mask sheet MS may be fixed to the mask frame MF by welding. In some aspects, in an embodiment, the mask sheet MS may have a circular shape corresponding to a shape of the opening area OA of the mask frame MF.

The mask sheet MS may include a body unit 410 and a sheet unit 420. The body unit 410 may include a silicone material. The body unit 410 may support the sheet unit 420 such that the sheet unit 420 is mounted thereon. In this case, the body unit 410 may include a first surface SF1, on which the sheet unit 420 is mounted, and a second surface SF2 facing the first surface SF1. In other words, the first surface SF1 may refer to an upper surface (surface in a +z direction) of the body unit 410, and the second surface SF2 may refer to a lower surface (surface in a −z direction) of the body unit 410.

In an embodiment, the body unit 410 may have an exterior formed to correspond to a shape of the mask frame MF. For example, the body unit 410 may be formed to have a circular shape corresponding to a shape of a perimeter of the mask frame MF. However, one or more embodiments are not limited thereto, and the body unit 410 may be formed in various polygonal shapes. Hereinbelow, for convenience of description, a case where the body unit 410 has a circular shape corresponding to the shape of the mask frame MF is mainly described.

In an embodiment, the body unit 410 may have a first opening OP1. For example, the body unit 410 may have a plurality of first openings OP1. For example, each of the plurality of first openings OP1 may be formed to have a rectangular shape. Each of the plurality of first openings OP1 may correspond to a shape of a display panel. In other words, each of the plurality of first openings OP1 may correspond to a shape of a cell.

For example, the body unit 410 may include a first rib 411 extending in a first direction (e.g., an x direction) in a plan view, and a second rib 412 extending in a second direction (e.g., a y direction) crossing the first direction. In an embodiment, the first rib 411 and the second rib 412 may each be provided in plurality. The plurality of first ribs 411 may be spaced apart from each other in the second direction and may extend parallel to each other. The plurality of second ribs 412 may be spaced apart from each other in the first direction and may extend parallel to each other. Accordingly, the plurality of first ribs 411 and the plurality of second ribs 412 may be arranged in a grid shape and may be disposed such that the plurality of first ribs 411 and the plurality of second ribs 412 define the plurality of first openings OP1. In other words, the first rib 411 and the second rib 412 may extend such that the first rib 411 and the second rib 412 surround the first opening OP1 and define the first opening OP1.

In an embodiment, a thickness of the body unit 410 may be about 600 μm to about 800 μm. For example, the thickness of the body unit 410 may be about 760 μm.

The sheet unit 420 may be disposed such that the 420 covers the first opening OP1. In an embodiment, the sheet unit 420 may include an inorganic material. For example, the sheet unit 420 may include at least one material of silicon oxide (SiOₓ), silicon nitride (SiNₓ), and silicon oxynitride (SiONₓ).

For example, as illustrated in FIG. 4, the sheet unit 420 may include a first film 421 and a second film 422. The first film 421 may be disposed on the body unit 410. The second film 422 may be disposed on the first film 421. The first film 421 may include silicon oxide in an embodiment. The first film 421 may be deposited on the body unit 410 or may be formed on the body unit 410 through an oxidization process.

The second film 422 may include silicon nitride in an embodiment. For example, the second film 422 may include silicon nitride (Si₃N₄). In this case, a density of the second film 422 may be about 2.9 g/cm³ to about 3.1 g/cm³, preferably, 2.98 g/cm³. In some aspects, tensile stress of the second film 422 may be about 50 MPa to about 300 MPa. The second film 422 may be formed by being deposited on the first film 421. The second film 422 may be formed by high-temperature deposition, e.g., deposition at about 700° C. to about 800° C. In an embodiment, the second film 422 may be deposited to a thickness of about 0.6 μm to about 1.8 μm. The second film 422 may form a low-stress film.

The sheet unit 420 may be disposed such that the sheet unit 420 covers the first opening OP1. In an example in which the first opening OP1 is provided in plurality, the sheet unit 420 may be disposed such that the sheet unit 420 covers the plurality of first openings OP1. The sheet unit 420 may be disposed on the body unit 410, in particular, on the first surface SF1 of the body unit 410. In some aspects, the sheet unit 420 may extend such that the sheet unit 420 surrounds an outer perimeter of the body unit 410, and the sheet unit 420 may further extend such that the sheet unit 420 covers the second surface SF2 of the body unit 410. In other words, the sheet unit 420 may cover the first surface SF1 of the body unit 410 and an outer peripheral surface of the body unit 410, and the sheet unit 420 may be disposed on part of the second surface SF2 of the body unit 410, e.g., on the second surfaces SF2 of the first rib 411 and the second rib 412.

In some aspects, because the sheet unit 420 may include the first film 421 and the second film 422, the first film 421 and the second film 422 may be sequentially stacked on the first surface SF1 of the body unit 410. In some aspects, the first film 421 and the second film 422 may be sequentially stacked on an outer surface (side surface) of the body unit 410. In some aspects, the first film 421 and the second film 422 may be sequentially stacked on part of the second surface SF2 of the body unit 410, i.e., on the second surfaces SF2 of the first rib 411 and the second rib 412.

In this case, the sheet unit 420 may include a plurality of second openings OP2. In other words, each of the first film 421 and the second film 422 may include openings overlapping each other and defining the second openings OP2. The plurality of second openings OP2 may be arranged (e.g., formed) in the sheet unit 420 on the (imaginary) first surface SF1 of the body unit 410 such that the plurality of second openings OP2 overlap the first opening OP1 of the body unit 410. In other words, the plurality of second openings OP2 may be arranged in one first opening OP1 such that the plurality of second openings OP2 overlap each other. In an embodiment, shapes of the plurality of second openings OP2 may correspond to a shape of a deposition pattern to be deposited on the display substrate DS. For example, the plurality of second openings OP2 may have a shape corresponding to an emission layer pattern of a pixel to be deposited on the display substrate DS. The deposition material may pass through the plurality of second openings OP2 and form an emission layer on the display substrate DS.

In this case, in an embodiment, each of the plurality of second openings OP2 may be reversely tapered. Reverse tapering may mean that each of the second openings OP2 is inclined such that widths of the second openings OP2 decrease toward the display substrate DS. Accordingly, in this case, a width W1 of the first film 421 between adjacent two openings OP2 may be less than a width W2 of the second film 422 between adjacent second openings OP2. Accordingly, a shadow phenomenon of a deposition material when the deposition material is incident toward the sheet unit 420 may be prevented.

In some embodiments, the mask sheet MS may further include an alignment key 440 between the first film 421 and the second film 422. The alignment key 440 may be disposed on the first film 421 and covered by the second film 422. The alignment key 440 may be arranged adjacent to a perimeter of the mask sheet MS such that the alignment key 440 does not overlap the first opening OP1 and the second opening OP2. The alignment key 440 may support alignment of the display substrate DS with the mask assembly MA in a deposition process of the display substrate DS.

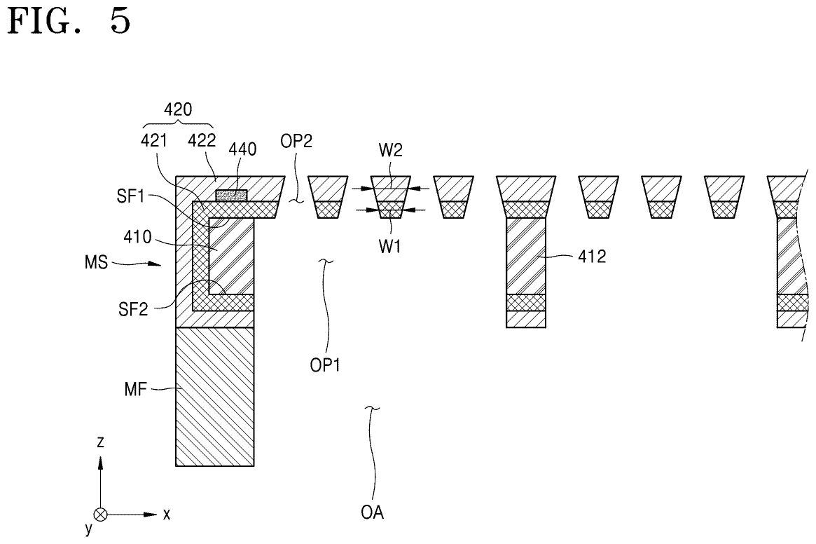

FIG. 5 is a cross-sectional view schematically illustrating a mask assembly according to an embodiment, similar to FIG. 4. The mask assembly according to the present embodiment is similar to the mask assembly described herein, and thus differences are mainly described herein.

Referring to FIG. 5, the mask frame MF is a frame that supports the mask sheet MS, and the mask frame MF may define the opening area OA in the center the mask sheet MS. In an embodiment, the mask frame MF may be a circular frame, and the opening area OA may be defined as circular. However, a shape of the mask frame MF is not limited thereto and may be various polygonal shapes. Hereinbelow, for convenience of description, a case in which the mask frame MF is a circular frame is mainly described. However, a shape of the mask frame MF is not limited thereto and may be various polygonal shapes. Hereinbelow, for convenience of description, a case in which the mask frame MF is a circular frame is mainly described.

The mask sheet MS may be installed on the mask frame MF. The opening area OA in the center of the mask frame MF may be covered by the mask sheet MS. In an embodiment, the mask sheet MS may be fixed to the mask frame MF by welding. In some aspects, in an embodiment, the mask sheet MS may have a circular shape corresponding to a shape of the opening area OA of the mask frame MF.

As described herein, the mask sheet MS may include a body unit 410 and a sheet unit 420. The body unit 410 may include a silicone material. The body unit 410 may support the sheet unit 420 such that the sheet unit 420 is mounted thereon. In an embodiment, the body unit 410 may have an exterior formed to correspond to the shape of the mask frame MF. For example, the body unit 410 may be formed to have a circular shape corresponding to a shape of a perimeter of the mask frame MF. However, one or more embodiments are not limited thereto, and the body unit 410 may be formed in various polygonal shapes. Hereinbelow, for convenience of description, a case where the body unit 410 has a circular shape corresponding to the shape of the mask frame MF is mainly described.

The body unit 410 may have the first opening OP1, e.g., the plurality of first openings OP1. For example, each of the plurality of first openings OP1 may be formed to have a rectangular shape. In some aspects, the body unit 410 may include the first rib 411 extending in the first direction (e.g., the x direction) in a plan view, and the second rib 412 extending in the second direction (e.g., the y direction) crossing the first direction. In an embodiment, each of the first rib 411 and the second rib 412 are provided in plurality, and the plurality of first ribs 411 and the plurality of second ribs 412 are arranged in a grid shape such that the plurality of first openings OP1 may be defined.

The sheet unit 420 may be disposed such that the sheet unit 420 covers the first opening OP1. In an embodiment, the sheet unit 420 may include an inorganic material. For example, the sheet unit 420 may include at least one material of silicon oxide (SiOₓ), silicon nitride (SiNₓ), and silicon oxynitride (SiONₓ).

For example, as illustrated in FIG. 5, the sheet unit 420 may include the first film 421 and the second film 422. The first film 421 may be disposed on the body unit 410. The second film 422 may be disposed on the first film 421.

In an embodiment, the first film 421 and the second film 422 may include silicon nitride. For example, the first film 421 and the second film 422 may include silicon nitride (Si₃N₄). The first film 421 and the second film 422 may include a same material having a same composition ratio, but are not limited thereto. For example, the first film 421 and the second film 422 may each include silicon nitride, but may be formed such that the silicon nitrides have different composition ratios. Hereinbelow, a case where the first film 421 and the second film 422 include a same material is mainly described.

In an embodiment, the densities of the first film 421 and the second film 422 may be about 2.9 g/cm³ to about 3.1 g/cm³, preferably, 2.98 g/cm³. In some aspects, tensile stress of the first film 421 tensile stress of the second film 422 may be about 50 MPa to about 300 MPa. The first film 421 may be formed by being deposited on the body unit 410, and the second film 422 may be formed by being deposited on the first film 421. The first film 421 and the second film 422 may be formed by high-temperature deposition, e.g., deposition at about 700° C. to about 800° C. In an embodiment, each of the first film 421 and the second film 422 may be deposited to a thickness of about 0.6 μm to about 1.8 μm. The first film 421 and the second film 422 as described herein may form a low-stress film.

The sheet unit 420 may be disposed such that the sheet unit 420 covers the first opening OP1. In an example in which the first opening OP1 is provided in plurality, the sheet unit 420 may be disposed such that the sheet unit 420 covers the plurality of first openings OP1. The sheet unit 420 may be disposed on the body unit 410, in particular, on the first surface SF1 of the body unit 410. In some aspects, the sheet unit 420 may extend such that the sheet unit 420 surrounds the outer perimeter of the body unit 410, and the sheet unit 420 may further extend such that the sheet unit 420 covers the second surface SF2 of the body unit 410. In other words, the sheet unit 420 may fully cover the first surface SF1 of the body unit 410 and an outer peripheral surface of the body unit 410, and the sheet unit 420 may be disposed on part of the second surface SF2 of the body unit 410, e.g., on the second surfaces SF2 of the first rib 411 and the second rib 412.

In some aspects, because the sheet unit 420 may include the first film 421 and the second film 422, the first film 421 and the second film 422 may be sequentially stacked on the first surface SF1 of the body unit 410. In some aspects, the first film 421 and the second film 422 may be sequentially stacked on the outer surface (side surface) of the body unit 410. In some aspects, the first film 421 and the second film 422 may be sequentially stacked on part of the second surface SF2 of the body unit 410, i.e., on the second surfaces SF2 of the first rib 411 and the second rib 412.

In this case, the sheet unit 420 may include the plurality of second openings OP2. In other words, each of the first film 421 and the second film 422 may include openings overlapping each other and defining the second openings OP2. The plurality of second openings OP2 may be arranged (e.g., formed) in the sheet unit 420 on the (imaginary) first surface SF1 of the body unit 410 such that the plurality of second openings OP2 overlap the first opening OP1 of the body unit 410. In other words, the plurality of second openings OP2 may be arranged in one first opening OP1 such that the plurality of second openings OP2 overlap each other. In an embodiment, the shapes of the plurality of second openings OP2 may correspond to the shape of a deposition pattern to be deposited on the display substrate DS. For example, the plurality of second openings OP2 may have a shape corresponding to an emission layer pattern of a pixel to be deposited on the display substrate DS. The deposition material may pass through the plurality of second openings OP2 and form an emission layer on the display substrate DS.

In this case, in an embodiment, each of the plurality of second openings OP2 may be reversely tapered. Reverse tapering may mean that each of the second openings OP2 is inclined such that the widths of the second openings OP2 decrease toward the display substrate DS. Accordingly, in this case, the width W1 of the first film 421 between adjacent two openings OP2 may be less than the width W2 of the second film 422 between adjacent second openings OP2. Accordingly, the shadow phenomenon of a deposition material when the deposition material is incident toward the sheet unit 420 may be prevented.

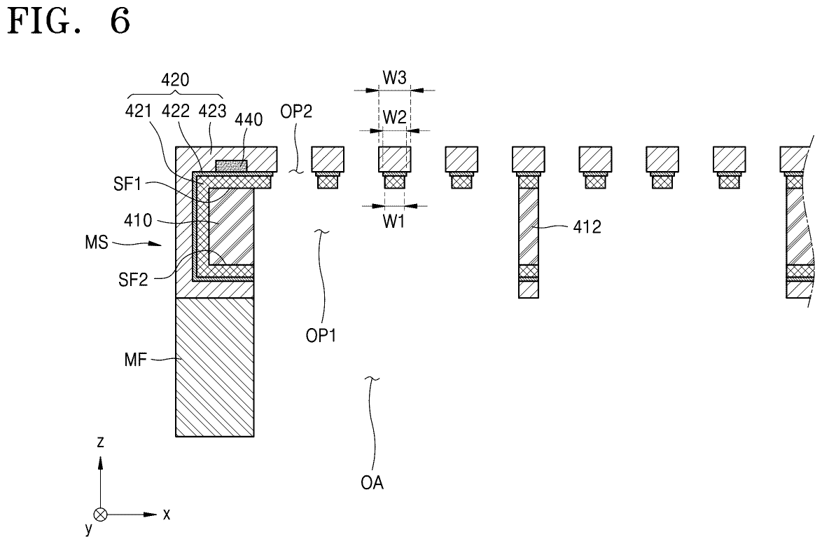

FIG. 6 is a cross-sectional view schematically illustrating a mask assembly according to an embodiment, similar to FIG. 4. The mask assembly according to the present embodiment is similar to the mask assembly described herein, and thus differences are mainly described herein.

Referring to FIG. 6, the mask frame MF is a frame that supports the mask sheet MS, and the mask frame MF may define the opening area OA in the center of the mask sheet MS. In an embodiment, the mask frame MF may be a circular frame, and the opening area OA may be defined as circular. However, a shape of the mask frame MF is not limited thereto and may be various polygonal shapes. Hereinbelow, for convenience of description, a case in which the mask frame MF is a circular frame is mainly described. However, a shape of the mask frame MF is not limited thereto and may be various polygonal shapes. Hereinbelow, for convenience of description, a case in which the mask frame MF is a circular frame is mainly described.

The mask sheet MS may be installed on the mask frame MF. The opening area OA in the center of the mask frame MF may be covered by the mask sheet MS. In an embodiment, the mask sheet MS may be fixed to the mask frame MF by welding. In some aspects, in an embodiment, the mask sheet MS may have a circular shape corresponding to a shape of the opening area OA of the mask frame MF.

As described herein, the mask sheet MS may include the body unit 410 and the sheet unit 420. The body unit 410 may include a silicone material. The body unit 410 may support the sheet unit 420 such that the sheet unit 420 is mounted thereon. In an embodiment, the body unit 410 may have an exterior formed to correspond to a shape of the mask frame MF. For example, the body unit 410 may be formed to have a circular shape corresponding to the shape of the perimeter of the mask frame MF. However, one or more embodiments are not limited thereto, and the body unit 410 may be formed in various polygonal shapes. Hereinbelow, for convenience of description, a case where the body unit 410 has a circular shape corresponding to the shape of the mask frame MF is mainly described.

The body unit 410 may have the first opening OP1, e.g., the plurality of first openings OP1. For example, each of the plurality of first openings OP1 may be formed to have a rectangular shape. In some aspects, the body unit 410 may include the first rib 411 extending in the first direction (e.g., the x direction) in a plan view, and the second rib 412 extending in the second direction (e.g., the y direction) crossing the first direction. In an embodiment, each of the first rib 411 and the second rib 412 are provided in plurality, and the plurality of first ribs 411 and the plurality of second ribs 412 are arranged in a grid shape such that the plurality of first openings OP1 may be defined.

The sheet unit 420 may be disposed such that the sheet unit 420 covers the first opening OP1. In an embodiment, the sheet unit 420 may include an inorganic material. For example, the sheet unit 420 may include at least one material of silicon oxide (SiOₓ), silicon nitride (SiNₓ), and silicon oxynitride (SiONₓ).

For example, as illustrated in FIG. 6, the sheet unit 420 may include the first film 421, the second film 422, and a third film 423. The first film 421 may be disposed on the body unit 410. The second film 422 may be disposed on the first film 421, and the third film 423 may be disposed on the second film 422.

In an embodiment, the first film 421 and the third film 423 may include silicon nitride. For example, the first film 421 and the third film 423 may include silicon nitride (Si₃N₄). The first film 421 and the third film 423 may include a same material having a same composition ratio, but are not limited thereto. For example, the first film 421 and the third film 423 may each include silicon nitride, but may be formed such that the silicon nitrides have different composition ratios. Hereinbelow, a case where the first film 421 and the third film 423 include a same material is mainly described.

In an embodiment, the densities of the first film 421 and the third film 423 may be about 2.9 g/cm³ to about 3.1 g/cm³, preferably, 2.98 g/cm³. In some aspects, tensile stress of the first film 421 tensile stress of the third film 423 may be about 50 MPa to about 300 MPa. The first film 421 may be formed by being deposited on the body unit 410, and the third film 423 may be formed by being deposited on the second film 422. The first film 421 and the third film 423 may be formed by high-temperature deposition, e.g., deposition at about 700° C. to about 800° C. In an embodiment, each of the first film 421 and the third film 423 may be deposited to a thickness of about 0.6 μm to about 1.8 μm. The first film 421 and the second film 422 as described herein may form a low-stress film.

The second film 422 may include silicon oxide in an embodiment. The second film 422 may be deposited on the first film 421 or may be formed on the first film 421 through an oxidization process. In other words, in this case, the second film 422 may be disposed between the first film 421 and the third film 423 each including silicon nitride.

The sheet unit 420 may be disposed such that the sheet unit 420 covers the first opening OP1. In an example in which the first opening OP1 is provided in plurality, the sheet unit 420 may be disposed such that the sheet unit 420 covers the plurality of first openings OP1. The sheet unit 420 may be disposed on the body unit 410, in particular, on the first surface SF1 of the body unit 410. In some aspects, the sheet unit 420 may extend such that the sheet unit 420 surrounds an outer perimeter of the body unit 410, and the sheet unit 420 may further extend such that the sheet unit 420 covers the second surface SF2 of the body unit 410. In other words, the sheet unit 420 may fully cover the first surface SF1 of the body unit 410 and the outer peripheral surface of the body unit 410, and the sheet unit 420 may be disposed on part of the second surface SF2 of the body unit 410, e.g., on the second surfaces SF2 of the first rib 411 and the second rib 412.

In some aspects, because the sheet unit 420 may include the first film 421, the second film 422, and the third film 423, the first film 421, the second film 422, and the third film 423 may be sequentially stacked on the first surface SF1 of the body unit 410. In some aspects, the first film 421, the second film 422, and the third film 423 may be sequentially stacked on the outer surface (side surface) of the body unit 410. In some aspects, the first film 421, the second film 422, and the third film 423 may be sequentially stacked on part of the second surface SF2 of the body unit 410, i.e., on the second surfaces SF2 of the first rib 411 and the second rib 412.

In this case, the sheet unit 420 may include a plurality of second openings OP2. In other words, each of the first film 421, the second film 422, and the third film 423 may include openings overlapping each other and defining the second openings OP2. The plurality of second openings OP2 may be arranged (e.g., formed) in the sheet unit 420 on the (imaginary) first surface SF1 of the body unit 410 such that the plurality of second openings OP2 overlap the first opening OP1 of the body unit 410. In other words, the plurality of second openings OP2 may be arranged in one first opening OP1 such that the second openings OP2 overlap each other. In an embodiment, shapes of the plurality of second openings OP2 may correspond to a shape of a deposition pattern to be deposited on the display substrate DS. For example, the plurality of second openings OP2 may have a shape corresponding to an emission layer pattern of a pixel to be deposited on the display substrate DS. The deposition material may pass through the plurality of second openings OP2 and form an emission layer on the display substrate DS.

In this case, in an embodiment, each of the plurality of second openings OP2 may be reversely tapered. Reverse tapering may mean that each of the second openings OP2 is inclined such that widths of the second openings OP2 decrease toward the display substrate DS. Accordingly, in this case, a width W1 of the first film 421 between adjacent two openings OP2 may be less than a width W2 of the second film 422 between adjacent second openings OP2. In some aspects, the width W2 of the second film 422 between adjacent second openings OP2 may be less than a width W3 of the third film 423 between adjacent second openings OP2. Accordingly, a shadow phenomenon of a deposition material when the deposition material is incident toward the sheet unit 420 may be prevented.

In some embodiments, the mask sheet MS may further include an alignment key 440 between the second film 422 and the third film 423. The alignment key 440 may be disposed on the second film 422 and covered by the third film 423. The alignment key 440 may be arranged adjacent to the perimeter of the mask sheet MS such that the alignment key 440 does not overlap the first opening OP1 and the second opening OP2. The alignment key 440 may support alignment of the display substrate DS with the mask assembly MA in the deposition process of the display substrate DS.

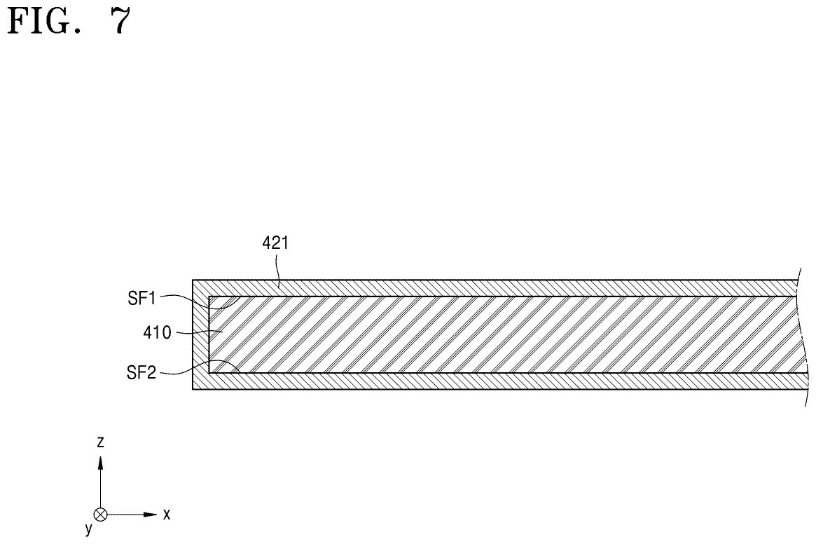

FIGS. 7 to 15 are diagrams schematically illustrating a method of manufacturing a mask assembly, according to an embodiment. In an embodiment, the method of manufacturing a mask assembly may be used to manufacture the mask assembly illustrated in FIG. 4 described herein, but is not limited thereto.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

Referring to FIG. 7, the method may include preparing the body unit 410 to manufacture the mask sheet MS. The body unit 410 may include a silicone material. Next, the method may include forming the first film 421 by oxidizing the body unit 410. In this case, the first film 421 may be disposed such that the first film 421 surrounds the entire surface of the body unit 410, e.g., the first film 421 may be disposed on all of the first surface SF1, the second surface SF2, and a side surface. In an embodiment, the first film 421 may include silicon oxide.

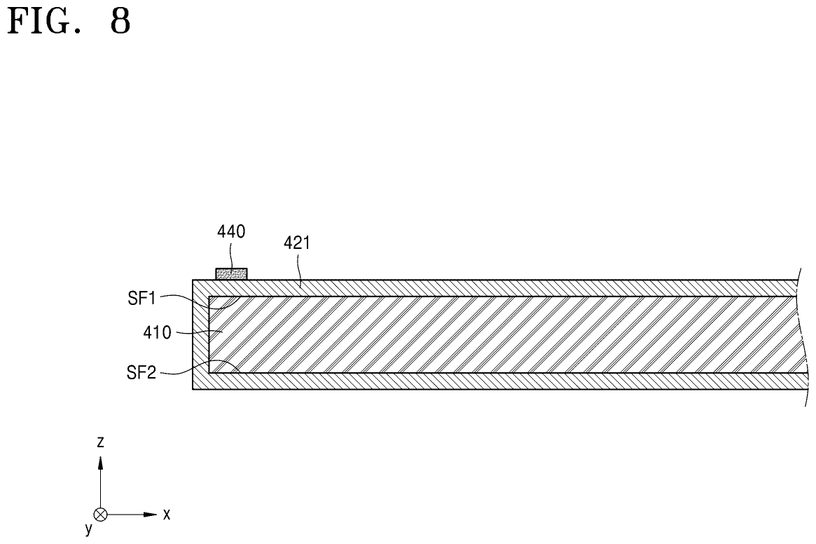

Referring to FIG. 8, the method may include disposing the alignment key 440 on the first film 421. The alignment key 440 may support alignment of the display substrate DS with the mask assembly MA in a deposition process of the display substrate DS.

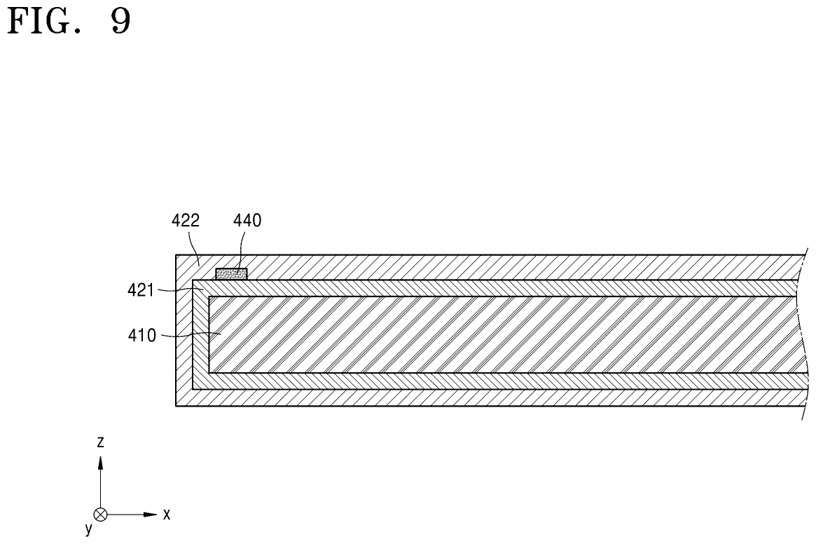

Referring to FIG. 9, the method may include forming the second film 422 on the first film 421. The second film 422 may be disposed such that the sheet unit 420 surrounds the entire surface of the first film 421. The second film 422 may include silicon nitride. In some aspects, in an embodiment, the second film 422 may be formed with a thickness of about 0.5 μm to about 1 μm. In an example in which the second film 422 is disposed such that the second film 422 surrounds the entire surface of the first film 421, stress applied to the second film 422 may be close to 0 (e.g., about 0). Accordingly, the second film 422 may be prevented from being deformed or distorted.

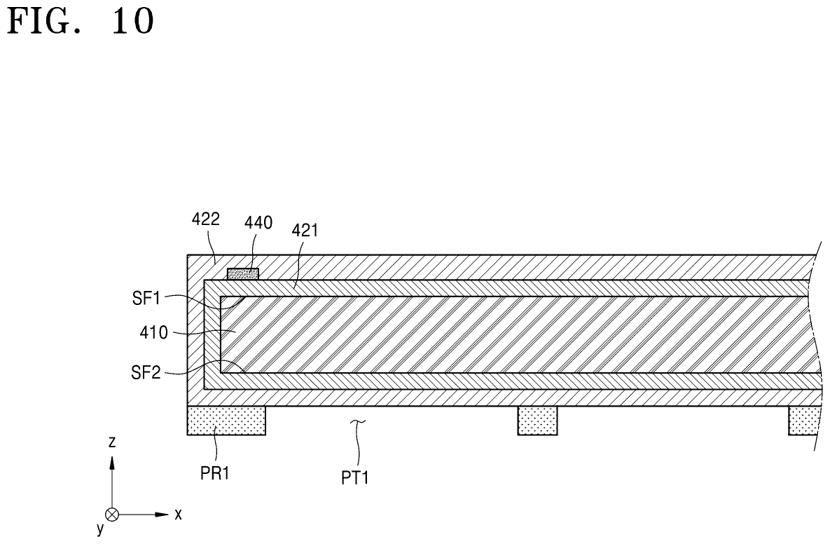

Referring to FIG. 10, the method may include disposing a first photoresist PR1 on the second film 422 arranged on the second surface SF2 side of the body unit. In this case, the first photoresist PR1 may have a first photo aperture PT1. The method may include forming first photo aperture PT1 by disposing the first photoresist PR1 on the second film 422 and then exposing part of the first photoresist PR1 (e.g., without exposing the entirety of the first photoresist PR1) through a photomask. It would be understood that the first photo aperture PT1 may be formed in a size and shape corresponding to the first opening OP1 to be described herein.

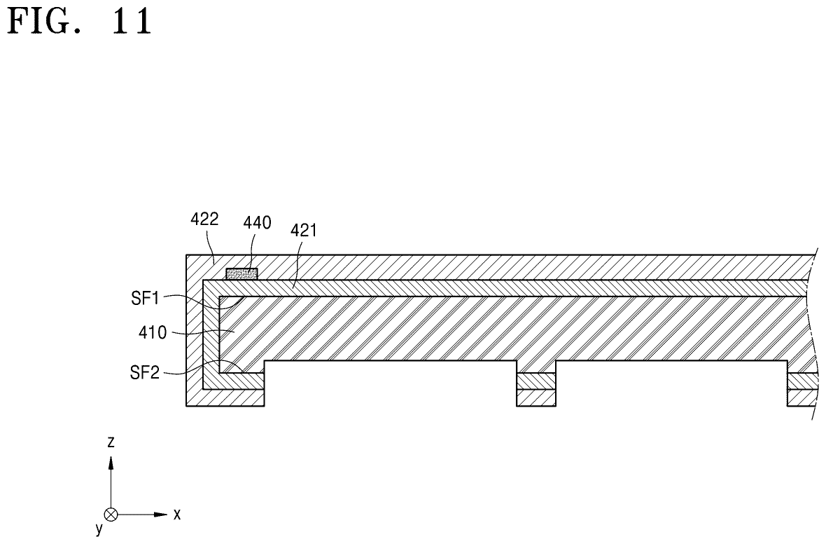

Referring to FIG. 11, the method may include etching the first film 421 and the second film 422 exposed through the first photoresist PR1, in particular, the first photo aperture PT1. For example, the method may include etching a portion exposed by the first photo aperture PT1 within the first film 421 and the second film 422 disposed on the second surface SF2 of the body unit 410. In this case, an etched portion of the first film 421 and the second film 422 may be defined as a first portion. The first portion corresponds to the first opening OP1 to be described herein, and the first portion may be a portion overlapping the first opening OP1 in a back view. In some aspects, in an embodiment, the method may include etching the first film 421 and the second film 422 by dry etching. In an example in which the first portions of the first film 421 and the second film 422 are etched as described herein, the second surface SF2 of the body unit 410 may be exposed.

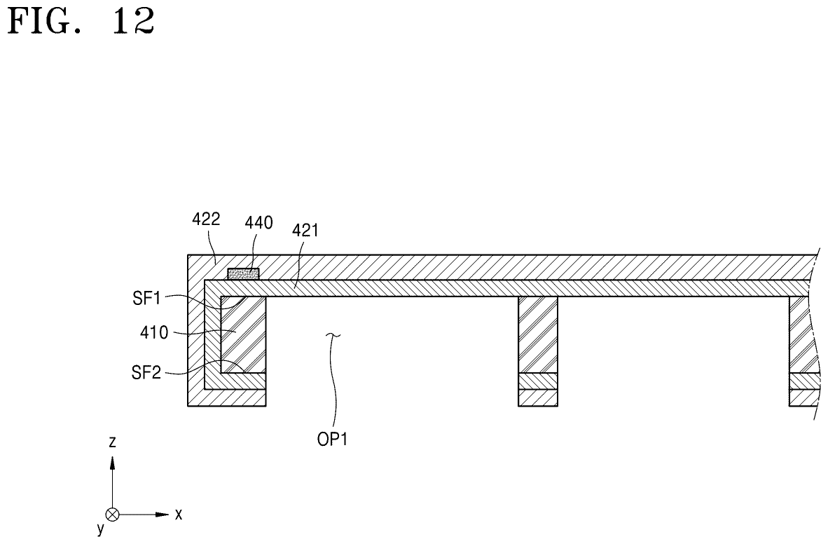

Referring to FIG. 12, the method may include etching the body unit 410 through the exposed second surface SF2 of the body unit 410. In this case, in an embodiment, the method may include etching the body unit 410 by wet etching. Because the second surface SF2 of the body unit 410 is exposed in a size and shape corresponding to the first photo aperture PT1, the body unit 410 may be etched in a corresponding size and shape to form the first opening OP1. In this case, the first film 421 positioned on the first surface SF1 side of the body unit 410 may function as a stopper layer during wet etching to stop etching. In some aspects, the first film 421 and the second film 422 positioned on the second surface SF2 side of the body unit 410 may function as a hard mask in a wet etching process for forming the first opening OP1. Through the process described herein, the body unit 410 may expose, through the first opening OP1, the first film 421 and the second film 422 arranged on the first surface SF1 side of the body unit 410.

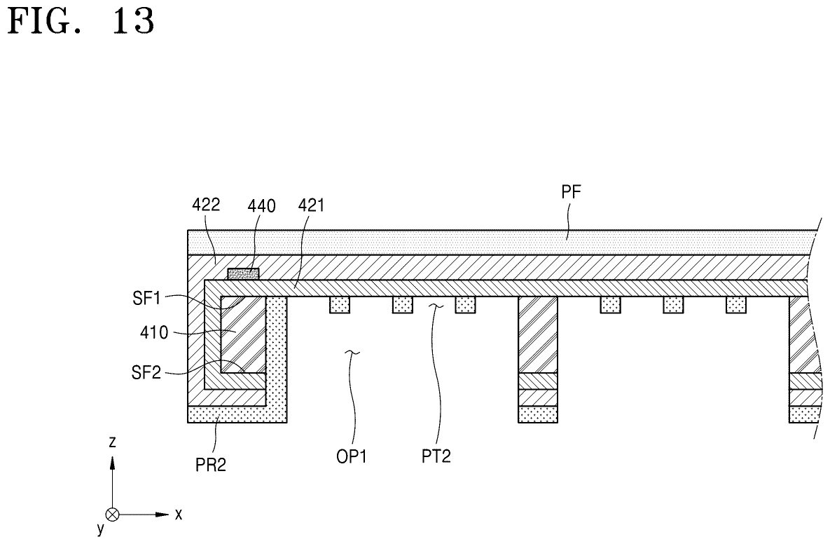

Referring to FIG. 13, the method may include disposing a second photoresist PR2 on the first film 421 exposed through the first opening OP1. In other words, the second photoresist PR2 may be arranged on a rear surface side of the mask sheet MS. In this case, the second photoresist PR2 may have a second photo aperture PT2. The method may include forming the second photo aperture PT2 by disposing the second photoresist PR2 on the first film 421 and then exposing part of the second photoresist PR2 (e.g., without exposing the entirety of the second photoresist PR2) through a photomask. It would be understood that the second photo aperture PT2 may be formed in a size and shape corresponding to the second opening OP2 to be described herein. In some aspects, in this case, the method may include disposing a protective layer PF on the second film 422. In an embodiment, the protective layer PF is an infrared film and may be a film layer that may be removed by irradiating the protective layer PF with ultraviolet rays. Alternatively, in another embodiment, the protective layer PF may be a photoresist layer formed by depositing a photoresist.

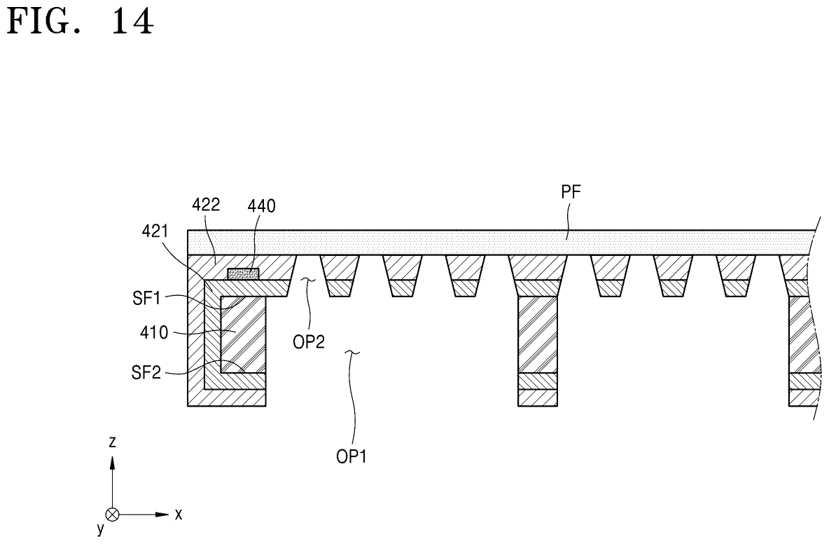

Referring to FIG. 14, the method may include etching the second photoresist PR2, in particular, the first film 421 and the second film 422 exposed through the second photo aperture PT2. For example, the method may include etching a portion exposed by the second photo aperture PT2 within the first film 421 and the second film 422 disposed on the first surface SF1 side of the body unit 410. In this case, an etched portion of the first film 421 and the second film 422 may be defined as a second portion.

The second portion corresponds to the second opening OP2. In other words, the method may include forming the second opening OP2 by etching and removing the second portions of the first film 421 and the second film 422. The second opening OP2 may be provided in plurality as described herein, and the plurality of second openings OP2 may be arranged such that the plurality of second openings OP2 overlap the first opening OP1. In some aspects, in an embodiment, the method may include etching the first film 421 and the second film 422 by dry etching. In this case, the protective layer PF may protect the first film 421 and the second film 422 from being deformed or damaged when the first film 421 and the second film 422 are etched. In some aspects, the second opening OP2 may be reversely tapered because etching is performed on the rear surface side of the mask sheet MS.

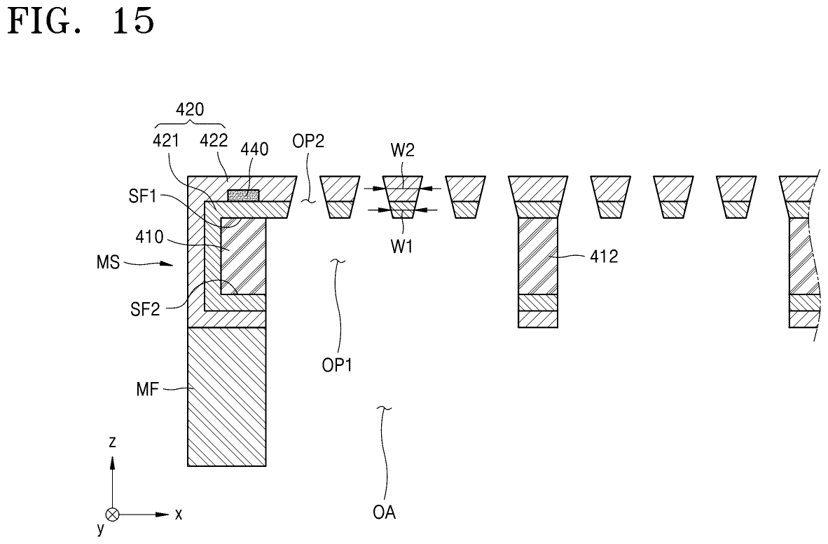

Referring to FIG. 15, the method may include manufacturing the mask sheet MS by removing the protective layer PF. The mask sheet MS may be connected and fixed to the mask frame MF. In an embodiment, the method may include fixing the mask sheet MS to the mask frame MF by welding.

As described herein, according to an embodiment, the sheet unit 420, e.g., the first film 421 and the second film 422, may undergo an etching process on the rear surface side of the mask sheet MS. Accordingly, the second opening OP2 may be reversely tapered, and a shadow phenomenon of a deposition material during a deposition process may be prevented. In some aspects, in the manufacturing method according to the present embodiment, a case where the first film 421 includes silicon oxide is mainly described, but in another embodiment, the first film 421 may include silicon nitride, as described with reference to FIG. 5.

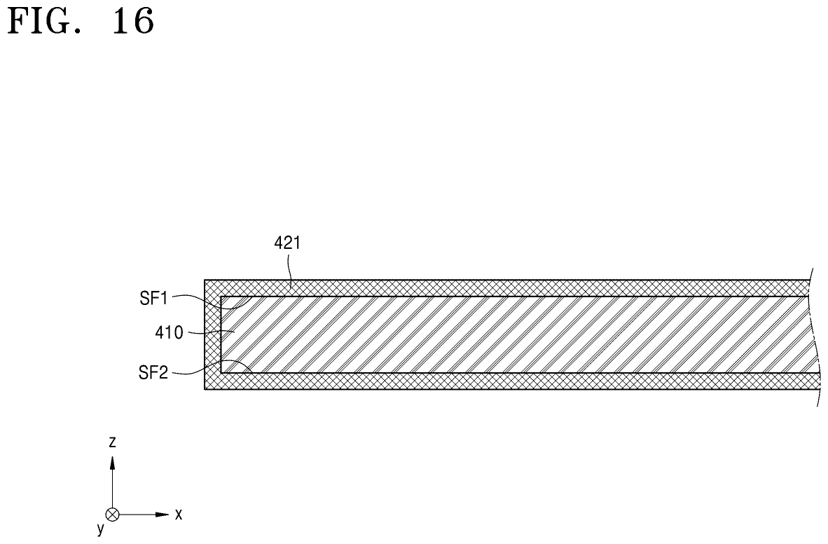

FIGS. 16 to 24 are diagrams schematically illustrating a method of manufacturing a mask assembly, according to an embodiment. In an embodiment, the method of manufacturing a mask assembly may be used to manufacture the mask assembly illustrated in FIG. 6 described herein, but is not limited thereto.

Referring to FIG. 16, the method may include preparing the body unit 410 to manufacture the mask sheet MS. The body unit 410 may include a silicone material. Next, the method may include forming the first film 421 such that the first film 421 surrounds the entire surface of the body unit 410, e.g., may be disposed on all of the first surface SF1, the second surface SF2, and a side surface. In an embodiment, the first film 421 may include silicon nitride.

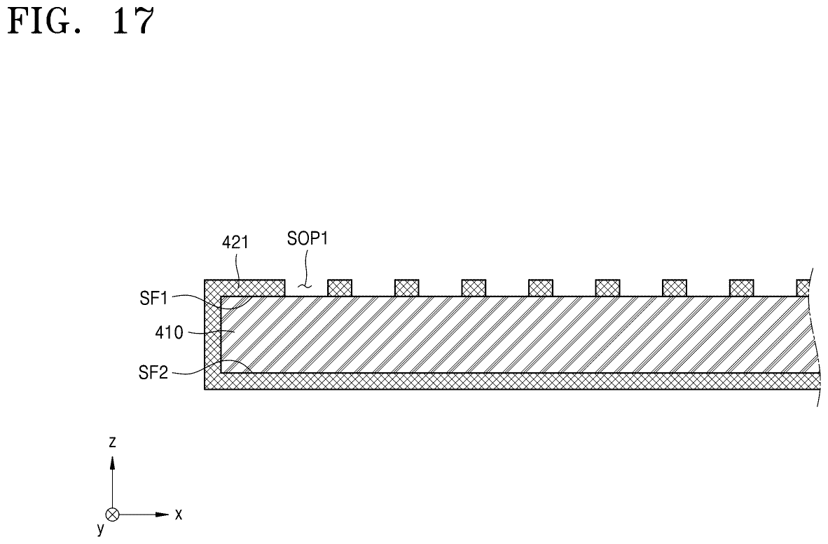

Referring to FIG. 17, the method may include etching part of the first film 421 arranged on the first surface SF1 side of the body unit 410. For example, the method may include etching the first film 421 to define the second openings OP2, and for example, the first film 421 may include a plurality of first sub-openings SOP1. In this case, the method may include etching the first film 421 by dry etching.

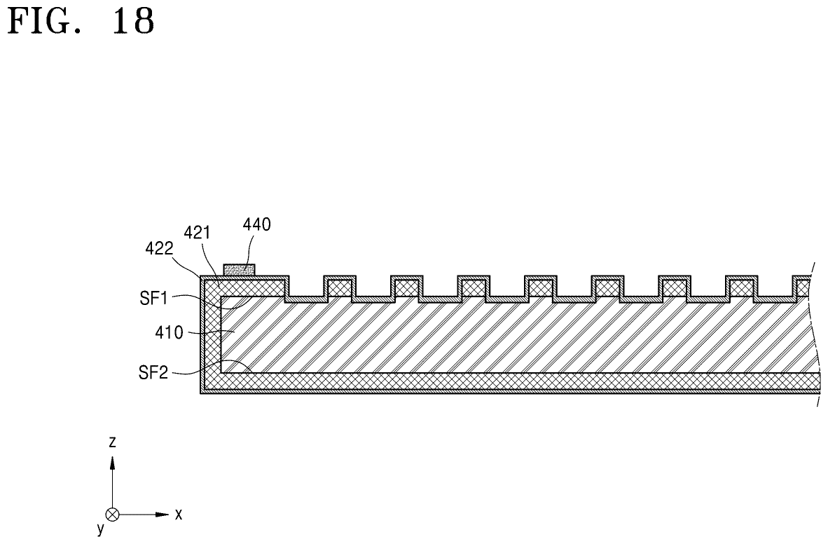

Referring to FIG. 18, the method may include forming the second film 422 on the first film 421. The method may include disposing the second film 422 such that the second film 422 surrounds the entire surface of the first film 421. In an embodiment, the second film 422 may include silicon oxide. In an embodiment, the method may include forming the second film 422 by oxidizing outer surfaces of the body unit 410 and the first film 421.

Accordingly, the method may include disposing the second film 422 on the first film 421 and on the first surface SF1 of the body unit 410 exposed by etching part of the first film 421. Accordingly, the second film 422 arranged on the first surface SF1 side of the body unit 410 may be provided in an uneven shape. In some aspects, the alignment key 440 may be disposed on the second film 422. The alignment key 440 may support alignment of the display substrate DS with the mask assembly MA in a deposition process of the display substrate DS.

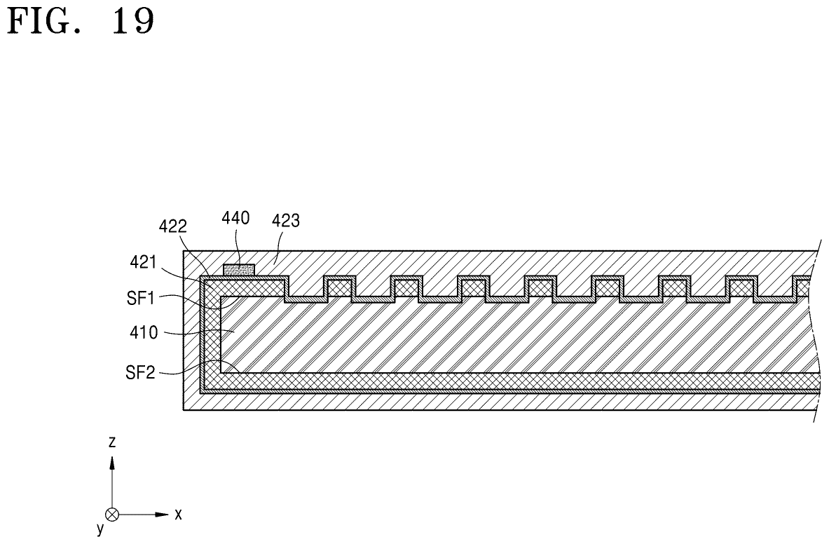

Referring to FIG. 19, the method may include forming the third film 423 on the second film 422. The method may include disposing the third film 423 such that the third film 423 surrounds the entire surface of the second film 422. The third film 423 may include silicon nitride. In some aspects, when the second film 422 arranged on the first surface SF1 side of the body unit 410 includes an uneven shape, the third film 423 may also include an uneven shape corresponding thereto.

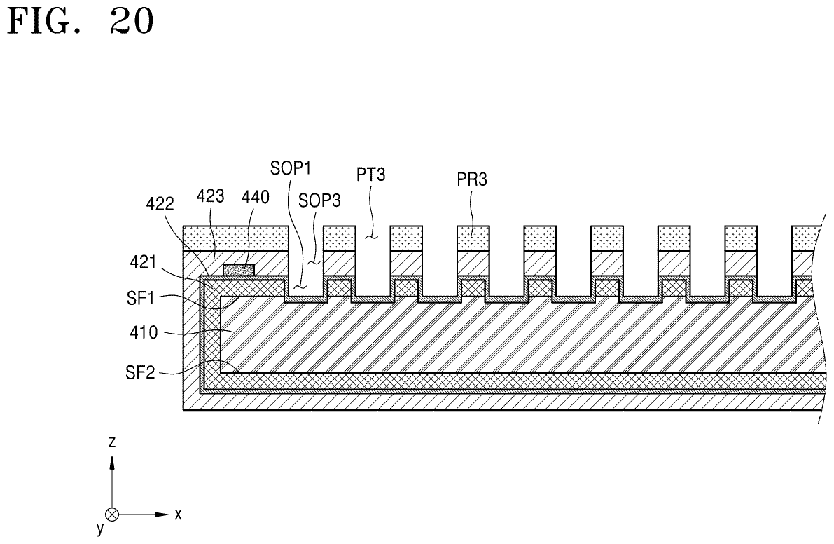

Referring to FIG. 20, the method may include disposing a third photoresist PR3 on the third film 423 arranged on the first surface SF1 side of the body unit 410. In this case, the third photoresist PR3 may have a third photo aperture PT3. The method may include forming the third photo aperture PT3 by disposing the third photoresist PR3 on the third film 423 and then exposing part of the third photoresist PR3 (e.g., without exposing the entirety of the third photoresist PR3) through a photomask. It would be understood that the third photo aperture PT3 may be formed in a size and shape corresponding to the second opening OP2. For example, the third photo aperture PT3 may be formed such that the third photo aperture PT3 overlaps the first sub-opening SOP1 corresponding to the first sub-opening SOP1.

Next, the method may include etching the third photoresist PR3, and in particular, the third film 423 exposed through the third photo aperture PT3. For example, the method may include etching a portion exposed by the third photo aperture PT3 within the third film 423 disposed on the first surface SF1 side of the body unit 410 to define the second opening OP2. For example, based on the etching, the third film 423 may include a plurality of third sub-openings SOP3. The third sub-opening SOP3 may be formed such that the third sub-opening SOP3 overlaps the first sub-opening SOP1 corresponding to the first sub-opening SOP1. In this case, the method may include etching the third film 423 by dry etching.

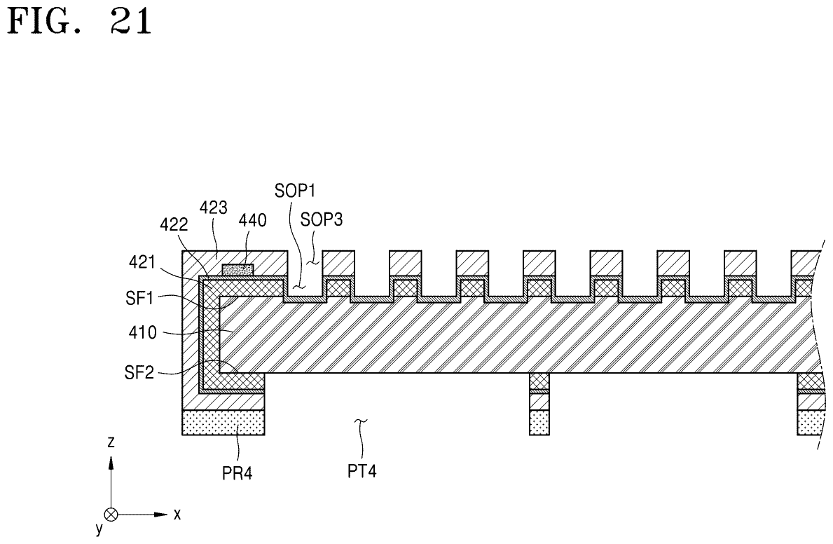

Referring to FIG. 21, the method may include removing the third photoresist PR3. In some aspects, the method may include disposing a fourth photoresist PR4 on the third film 423 disposed on the second surface SF2 side of the body unit 410. In this case, the fourth photoresist PR4 may have a fourth photo aperture PT4. The method may include forming the fourth photo aperture PT4 by disposing the fourth photoresist PR4 on the third film 423 and then exposing part of the fourth photoresist PR4 (e.g., without exposing the entirety of the fourth photoresist PR4) through a photomask. It would be understood that the fourth photo aperture PT4 may be formed in a size and shape corresponding to the first opening OP1 to be described herein.

Next, the method may include etching the fourth photoresist PR4, in particular, the third film 423, the second film 422, and the first film 421 exposed through the fourth photo aperture PT4. For example, the method may include etching a portion exposed by the fourth photo aperture PT4 within the first film 421, the second film 422, and the third film 423 disposed on the second surface SF2 of the body unit 410. In this case, an etched portion of the first film 421, the second film 422, and the third film 423 may be defined as a first portion. The first portion corresponds to the first opening OP1 to be described herein and may be a portion overlapping the first opening OP1 in a back view. In some aspects, in an embodiment, the method may include etching the first film 421, the second film 422, and the third film 423 by dry etching. In an example in which the first portions of the first film 421, the second film 422, and the third film 423 are etched as described herein, the second surface SF2 of the body unit 410 may be exposed.

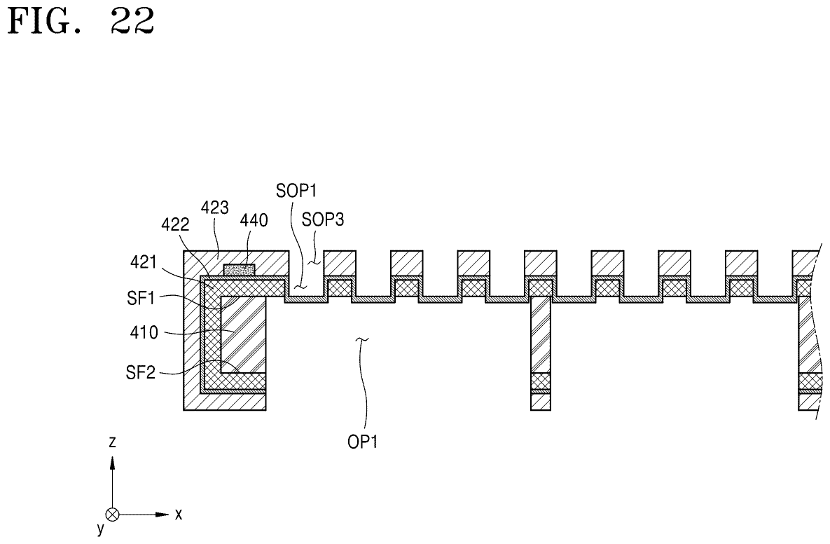

Referring to FIG. 22, the method may include etching the body unit 410 through the exposed second surface SF2 of the body unit 410. In this case, in an embodiment, the method may include etching the body unit 410 by wet etching. Because the second surface SF2 of the body unit 410 is exposed in a size and shape corresponding to the fourth photo aperture PT4, the body unit 410 may be etched in a corresponding size and shape to form the first opening OP1. In this case, the first film 421, the second film 422, and the third film 423 positioned on the second surface SF2 side of the body unit 410 may function as a hard mask in a wet etching process for forming the first opening OP1. Through the process described herein, the body unit 410 may expose, through the first opening OP1, the first film 421 and the second film 422 arranged on the first surface SF1 side of the body unit 410.

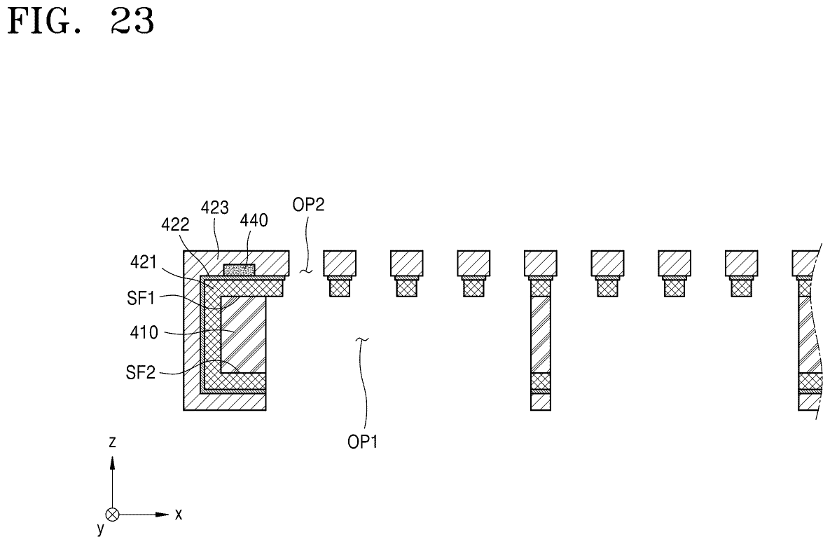

Referring to FIG. 23, the method may include performing wet etching through the first opening OP1. In this case, the method may include performing wet etching by using a buffered oxide etchant (BOE) solution. Accordingly, the second film 422 including silicon oxide may be etched. For example, the second film 422 positioned between the first film 421 and the third film 423 within the second film 422 is not etched, and the exposed second film 422 may be etched and removed. Accordingly, the second film 422 may define the second opening OP2 together with the first film 421 and the third film 423.

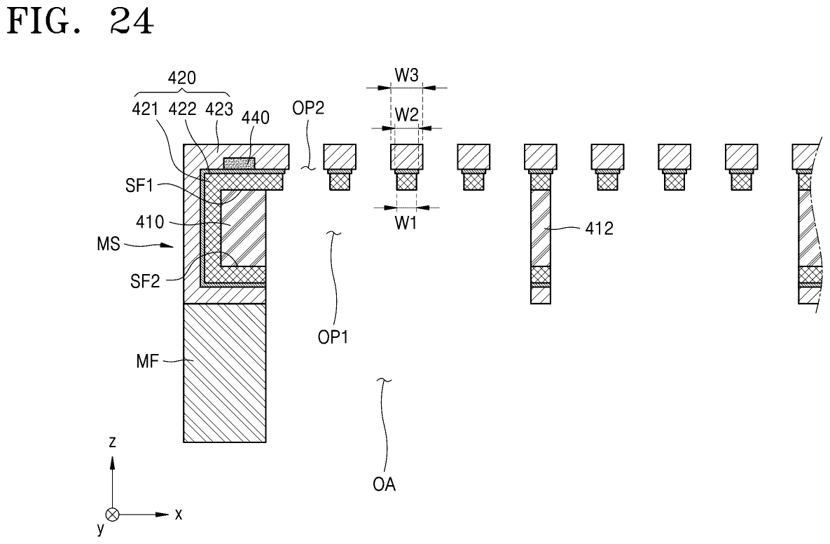

Referring to FIG. 24, the method may include connecting and fixing the mask sheet MS to the mask frame MF. In an embodiment, the method may include fixing the mask sheet MS to the mask frame MF by welding.

As described herein, according to an embodiment, the second opening OP2 of the sheet unit 420 may be reversely tapered, and a shadow phenomenon of a deposition material during a deposition process may be prevented.

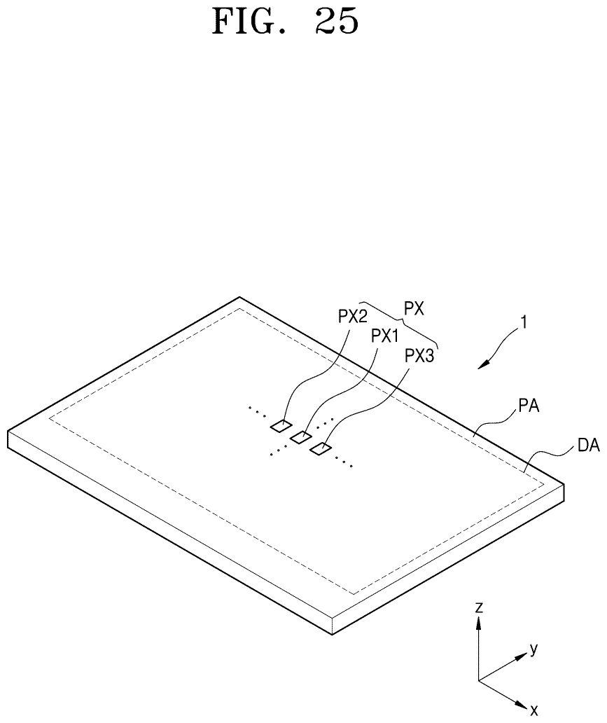

FIG. 25 is a perspective view schematically illustrating a display device 1 manufactured by using a manufacturing device for a display device, according to an embodiment.

Referring to FIG. 25, the display device 1 may include a display area DA, on which images are implemented, and a peripheral area PA in which no image is implemented. The display device 1 may provide images through an array of a plurality of pixels, which are two-dimensionally arranged on an x-y plane. Each of the pixels may include different sub-pixels. Each of the sub-pixels may emit light of different colors and may be, for example, one of a green sub-pixel, a red sub-pixel, and a blue sub-pixel.

In an embodiment, the plurality of sub-pixels may include a first sub-pixel PX1, a second sub-pixel PX2, and a third sub-pixel PX3. Hereinbelow, for convenience of description, a case is described in which the first sub-pixel PX1 is a green sub-pixel, the second sub-pixel PX2 is a red sub-pixel, and the third sub-pixel PX3 is a blue sub-pixel.

The first sub-pixel PX1, the second sub-pixel PX2, and the third sub-pixel PX3 are areas in which green, red, and blue light may be emitted, respectively, and the display device 1 may provide images by using the light emitted from the sub-pixels.

The peripheral area PA is an area in which no image is provided, and the peripheral area PA may surround the display area DA entirely. A driver or main voltage line for providing electrical signals or power to pixel circuits may be arranged in the peripheral area PA. The peripheral area PA may include a pad to which an electronic element or a printed circuit board may be electrically connected.

The display area DA may have a polygonal shape such as, for example, a rectangle, as illustrated in FIG. 25. For example, the display area DA may have a rectangular shape of which a horizontal length is greater than a vertical length, a rectangular shape of which the horizontal length is less than the vertical length, or a square shape. In another embodiment, the display area DA may be a circle, an ellipse, or a polygon, such as, for example, a triangle or pentagon. In some aspects, in FIG. 25, the display device 1 is a flat display device having a flat shape, but the display device 1 may be implemented such that the display device 1 is flexible, foldable, or rollable into various shapes.

The display device 1 may be used not only for portable electronic devices, such as, for example, mobile phones, smartphones, tablet personal computers (PCs), mobile communication terminals, electronic notebooks, electronic books, portable multimedia players (PMPs), navigations, and ultra mobile PCs (UMPCs), but also as display screens of various products such as, for example, televisions, laptops, monitors, billboards, and Internet of Things (IoT). In some aspects, the display device 1 according to an embodiment may be used for wearable devices such as, for example, smart watches, watch phones, glasses-type displays, and head-mounted displays (HMDs). In some aspects, the display device 1 according to an embodiment may be used for instrument panels of vehicles, center information displays (CIDs) disposed on center fascias or dashboards, mirror displays replacing side-view mirrors of vehicles, or as a display screen disposed on rear surfaces of front seats as an entertainment for backseat passengers of a vehicle.

In some aspects, hereinbelow, it is described that the display device 1 includes an organic light-emitting diode (OLED) as a display element of the display device 1, but the display device 1 of one or more embodiments is not limited thereto. In another embodiment, the display device 1 may be a light-emitting display device including an inorganic light-emitting diode, i.e., an inorganic light-emitting display. In another embodiment, the display device 1 may be a quantum dot light-emitting display.

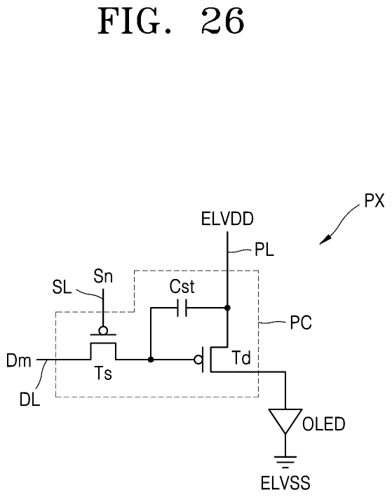

FIG. 26 is an equivalent circuit diagram of one pixel circuit PC included in a display device, the display device being manufactured by using a manufacturing device for a display device, according to an embodiment. The pixel circuit PC may be electrically connected to a display element, and one display element may correspond to one pixel PX. For example, the display element may be an organic light-emitting diode OLED.

The pixel circuit PC may include a first transistor Td, a second transistor Ts, and a storage capacitor Cst. The second transistor Ts, which is a switching transistor, may be connected to a scan line SL and a data line DL, and the second transistor Ts may be turned on according to a switching signal received via the scan line SL and may transfer a data signal received via the data line DL to the first transistor Td. The storage capacitor Cst may have one end electrically connected to the second transistor Ts and the other end electrically connected to a driving voltage line PL, and the storage capacitor Cst may store a voltage corresponding to the difference between a voltage received from the second transistor Ts and a driving power voltage ELVDD supplied to the driving voltage line PL.

The first transistor Td, which is a driving transistor, may be connected to the driving voltage line PL and the storage capacitor Cst and may control a magnitude of a driving current flowing from the driving voltage line PL to the organic light-emitting diode OLED in response to a voltage value stored in the storage capacitor Cst. The organic light-emitting diode OLED may emit light having a certain luminance according to the driving current. An opposite electrode 230 of the organic light-emitting diode OLED may receive an electrode power voltage ELVSS.

In FIG. 26, the pixel circuit PC includes two transistors and one storage capacitor. However, one or more embodiments are not limited thereto. For example, the number of transistors and storage capacitors may vary depending on a design of the pixel circuit PC.

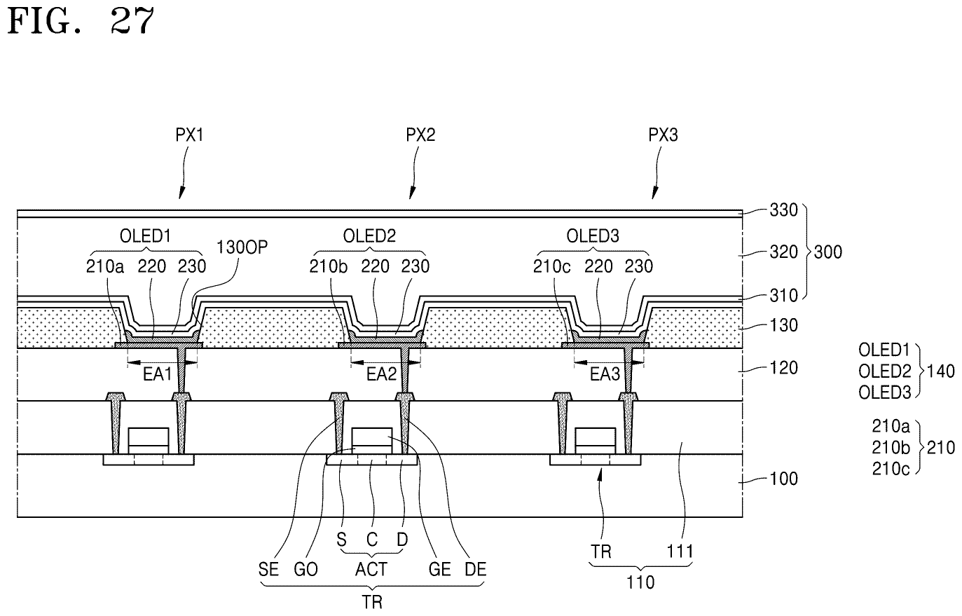

FIG. 27 is a cross-sectional view schematically illustrating a display device manufactured by using a manufacturing device for a display device, according to an embodiment.

Referring to FIG. 27, the display device 1 may include the substrate 100, a pixel circuit layer 110 including a transistor TR, a via insulating layer 120 on the pixel circuit layer 110, a display element layer 140 disposed on the via insulating layer 120, and an encapsulation layer 300 on the display element layer 140.

In a plan view, the substrate 100 may have an upper surface extending in an x direction and y direction. The substrate 100 may include a semiconductor material, e.g., Group IV semiconductor, Group III-V compound semiconductor, or Group II-VI compound semiconductor. In other words, the substrate 100 may be a semiconductor substrate including a semiconductor material. For example, the substrate 100 may include silicon (Si). In other words, the substrate 100 may include a Si substrate (a Si semiconductor substrate). For example, the substrate 100 may be a silicon wafer. The silicon wafer may be a monocrystalline silicon wafer, a polycrystalline silicon wafer, or an amorphous silicon wafer.

In this way, an organic light-emitting diode display device using a semiconductor substrate as the substrate 100 may be called an OLED on Silicon (OLEDOS). Because OLEDOS uses a semiconductor substrate as the substrate 100, a transistor manufacturing process or the like commonly used in the field of semiconductor technology may be applied to a manufacturing process for a display device. Accordingly, because formation of ultra-small pixels and control of these pixels are possible, OLEDOS may display ultra-high-resolution images.

In some cases, a type of the substrate 100 may not be limited to a semiconductor substrate. For example, the substrate 100 may include glass, metal, or polymer resin. In some aspects, the substrate 100 may include polymer resin such as, for example, polyethersulfone, polyacrylate, polyetherimide, polyethylene naphthalate, polyethylene terephthalate, polyphenylene sulfide, polyarylate, polyimide, polycarbonate, or cellulose acetate propionate. However, various modifications may be made to the substrate 100. For example, the substrate 100 may have a multi-layer structure that includes two layers, each including polymer resin, and a barrier layer between the two layers, the barrier layer including an inorganic material such as, for example, silicon oxide (SiOₓ), silicon nitride (SiNₓ), and/or silicon oxynitride (SiOₓN_{y}). Hereinbelow, a case where the substrate 100 is a silicon substrate is described in detail.

The pixel circuit layer 110 may be disposed on the substrate 100. The pixel circuit layer 110 may include a plurality of pixel circuits corresponding to pixels described with reference to FIG. 17, i.e., the first sub-pixel to the third sub-pixel PX1, PX2, and PX3, respectively, and each of the plurality of pixel circuits may include a transistor and/or storage capacitor, as described with reference to FIG. 12. The pixel circuit layer 110 may include at least one transistor TR and at least one insulating layer.

In FIG. 27, the organic light-emitting diode OLED, which is a display element, is positioned on the substrate 100. In an example in which the organic light-emitting diode OLED is electrically connected to the pixel circuit PC, it may be understood that a pixel electrode 210 included in the organic light-emitting diode OLED is electrically connected to the transistor TR included in the pixel circuit PC. For convenience of illustration, in FIG. 27, the transistors TR respectively connected to a first organic light-emitting diode to a third organic light-emitting diode OLED1, OLED2, and OLED3 are illustrated, and these transistors TR may each correspond to the first transistor Td described herein.

The transistor TR may include a gate dielectric layer GO, a gate electrode GE, and an active area ACT. The transistor TR may be, for example, a metal-oxide-semiconductor field effect transistor (MOSFET), but is not limited thereto. In an embodiment, each of the transistors TR may be separated from each other by an element separation area, which is disposed between the transistors TR.

The active area ACT may be arranged within the substrate 100. The active area ACT may be formed as part of the substrate 100. The active area ACT may be arranged to extend in a first direction, e.g., an x direction, within the substrate 100. A portion of the substrate 100 may be recessed, and the active area ACT may be disposed on the recessed substrate 100. The active area ACT may include a channel region C, a drain region D, and a source region S, wherein the drain region D and the source region S are at opposite sides of the channel region C, respectively. The drain region D and the source region S may be areas obtained by doping impurities onto the substrate 100 including a semiconductor material. The channel region C may overlap the gate electrode GE.

The gate dielectric layer GO may be disposed between the gate electrode GE and the active area ACT. For example, the gate dielectric layer GO may include an inorganic insulating material such as, for example, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

The gate electrode GE may be disposed on the active area ACT. The gate electrode GE may be arranged to cross the active area ACT and extend in one direction, e.g., a y direction. The channel region C of the transistor TR may be formed in the active area ACT crossing the gate electrode GE. In other words, the gate electrode GE may overlap the channel region C of the transistor TR. The gate electrode GE may be disposed on the gate dielectric layer GO. The gate electrode GE may include a conductive material. For example, the gate electrode GE may include a metal nitride, such as, for example, a titanium nitride film (TiN), a tantalum nitride film (TaN), or a tungsten nitride film (WN), and/or a metal material such as, for example, aluminum (Al), tungsten (W), copper (Cu), or molybdenum (Mo), or a semiconductor material such as, for example, doped polysilicon. The gate electrode GE may be formed as a multi-layer or single layer including the materials described herein.

An interlayer insulating layer 111 may be disposed on the substrate 100 and may cover the transistor TR. The interlayer insulating layer 111 may include at least one of an oxide, a nitride, and an oxynitride. The interlayer insulating layer 111 may be formed of a single layer or multi-layer structure.

A drain electrode DE and a source electrode SE may be positioned on the interlayer insulating layer 111. The drain electrode DE and the source electrode SE may be connected to the drain region D and the source electrode SE of the active area ACT, respectively, through contact holes provided in the interlayer insulating layer 111. The drain electrode DE and the source electrode SE may include a material with good conductivity. The drain electrode DE and the source electrode SE may include a conductive material, including Mo, Al, Cu, Ti, and may be formed of a multi-layer or single layer including the materials described herein.

The via insulating layer 120 may be disposed on the pixel circuit layer 110. The via insulating layer 120 covers upper surfaces of the drain electrode DE and the source electrode SE and has a substantially flat upper surface, and may thus be an organic insulating layer which serves as a planarization film. For example, the via insulating layer 120 may include an organic material such as, for example, acryl, benzocyclobutene (BCB), or hexamethyldisiloxane (HMDSO). In FIG. 27, the via insulating layer 120 is illustrated as a single layer. However, one or more embodiments are not limited thereto, and the via insulating layer 120 may be formed as a multi-layer.

The display element layer 140 may be disposed on the via insulating layer 120. The display element layer 140 may include the first organic light-emitting diode OLED1, the second organic light-emitting diode OLED2, and the third organic light-emitting diode OLED3.

The first to third organic light-emitting diodes OLED1, OLED2, and OLED3 may include a stack structure of the pixel electrode 210, an emission layer 220, and the opposite electrode 230. The first to third organic light-emitting diodes OLED1, OLED2, and OLED3 may each emit light having the same peak spectrum. For example, the first to third organic light-emitting diodes OLED1, OLED2, and OLED3 may each emit white light. For example, a peak spectrum of each of the first to third organic light-emitting diodes OLED1, OLED2, and OLED3 may have a peak in a first wavelength range of about 435 nm to about 490 nm, a second wavelength range of about 500 nm to about 590 nm, and a third wavelength range of about 600 nm to about 710 nm. The first to third organic light-emitting diodes OLED1, OLED2, and OLED3 emit light, and areas in which the light is emitted may be defined as first to third emission areas EA1, EA2, and EA3, respectively.

A plurality of pixel electrodes 210 may be disposed on the via insulating layer 120. The pixel electrodes 210 may be electrically connected to the transistors TR through the contact holes provided in the via insulating layer 120. Each of the pixel electrodes 210 may include a light-transmitting conductive layer and a reflective layer, wherein the light-transmitting conductive layer being formed of a light-transmitting conductive oxide such as, for example, indium tin oxide (ITO), indium oxide (In2O3), or indium zinc oxide (IZO), and the reflective layer being formed of a metal such as, for example, Al or silver (Ag). For example, each of the pixel electrodes 210 may have a three-layer structure of ITO/Ag/ITO.

As illustrated in FIG. 27, the pixel electrodes 210 may include a first pixel electrode 210a, a second pixel electrode 210b, and a third pixel electrode 210c. The first to third pixel electrodes 210a, 210b, and 210c may be spaced apart from each other when viewed from a direction perpendicular to the substrate 100.

A pixel-defining layer 130 may be disposed over the via insulating layer 120. The pixel-defining layer 130 may include openings 130OP respectively corresponding to the first to third sub-pixels PX1, PX2, and PX3. The openings 130OP of the pixel-defining layer 130 may expose at least a portion, e.g., a central portion, of the pixel electrodes 210, respectively. In an embodiment, the first to third emission areas EA1, EA2, and EA3 may be respectively defined as areas exposed by the openings 130OP of the pixel-defining layer 130. The pixel-defining layer 130 may include an organic insulating material and/or an inorganic insulating material. For example, the pixel-defining layer 130 may include an organic material such as, for example, polyimide or HMDSO.

A spacer (not illustrated) for preventing mask scratches may be further included on the pixel-defining layer 130. In an embodiment, the spacer may be integrally formed as a single body with the pixel-defining layer 130. For example, the spacer and the pixel-defining layer 130 may be simultaneously formed in the same process by using a halftone mask process.

The emission layer 220 may be disposed on the pixel electrodes 210. The emission layer 220 may be disposed such that the emission layer 220 covers the pixel electrodes 210 exposed by the openings 130OP of the pixel-defining layer 130. In an embodiment, the emission layer 220 may be integrally formed as a single body across the plurality of pixel electrodes 210.

The emission layer 220 may emit light of a certain color. For example, the emission layer 220 may emit white light.

In an embodiment, the emission layer 220 may include a polymer organic material or a low-molecular weight organic material. The emission layer 220 may include an organic emission layer. For example, the emission layer 220 may include a polymer material such as, for example, a polyphenylene vinylene (PPV)-based material or a polyfluorene-based material. The emission layer 220 may be formed by screen printing, inkjet printing, laser induced thermal imaging (LITI), etc. However, one or more embodiments are not limited thereto, and the emission layer 220 may include an inorganic emission material or quantum dots.

In an embodiment, a functional layer (not illustrated) may be disposed under and over the emission layer 220. The functional layer may include a hole injection layer (HIL), a hole transport layer (HTL), an electron transport layer (ETL), and/or an electron injection layer (EIL). These functional layer may be integrally provided as a single body across the plurality of pixel electrodes 210, or may be patterned to correspond to each of the plurality of pixel electrodes 210.

The opposite electrode 230 may be disposed on the pixel electrodes 210 and may overlap the pixel electrodes 210. The opposite electrode 230 may be disposed on the emission layer 220. The opposite electrode 230 may include a conductive material having a low work function. For example, the opposite electrode 230 may include a (semi-) transparent layer including silver (Ag), magnesium (Mg), aluminum (Al), platinum (Pt), palladium (Pd), gold (Au), nickel (Ni), neodymium (Nd), iridium (Ir), chrome (Cr), lithium (Li), calcium (ca), or an alloy thereof. Alternatively, the opposite electrode 230 may further include a layer such as, for example, ITO, IZO, ZnO, or In₂O₃, on the (semi-)transparent layer including the materials described herein. The opposite electrode 230 may be integrally formed as a single body which covers the substrate 100 entirely.

The encapsulation layer 300 may be disposed on the opposite electrode 230. The encapsulation layer 300 may be disposed such that the encapsulation layer 300 covers the plurality of organic light-emitting diodes OLED1, OLED2, and OLED3. The encapsulation layer 300 may include at least one inorganic encapsulation layer and at least one organic encapsulation layer. In an embodiment, the encapsulation layer 300 may include a first inorganic encapsulation layer 310, an organic encapsulation layer 320, on the first inorganic encapsulation layer 310, and a second inorganic encapsulation layer 330.

The first inorganic encapsulation layer 310 and the second inorganic encapsulation layer 330 may include one or more inorganic materials of aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include acryl-based resin, epoxy-based resin, polyimide, polyethylene, etc. In an embodiment, the organic encapsulation layer 320 may include acrylate. The organic encapsulation layer 320 may be formed by curing a monomer or coating a polymer. The organic encapsulation layer 320 may be transparent.

Although not illustrated on the encapsulation layer 300, a touch sensor layer may be disposed on the encapsulation layer 300, and an optical functional layer may be disposed on the touch sensor layer. The touch sensor layer may obtain coordinate information according to an external input, e.g., a touch event. The optical functional layer may reduce reflectivity of light (external light) incident from the outside toward the display device, and/or may improve color purity of light emitted from the display device. In an embodiment, the optical functional layer may include a retarder and/or a polarizer. The retarder may be of a film type or liquid crystal coating type, and the retarder may include a λ/2 retarder and/or a λ/4 retarder. The polarizer may also be of a film type or liquid crystal coating type. The film-type may include a stretchable synthetic resin film, and the liquid crystal coating type may include liquid crystals arranged in a certain array. The retarder and the polarizer may further include a protective film.

An adhesive member may be disposed between the touch sensor layer and the optical functional layer. The adhesive member may be any one known in the art without limitation. In an embodiment, the adhesive member may be a pressure sensitive adhesive (PSA).

According to the one or more embodiments, a mask sheet may a reverse tapered opening, thereby preventing a shadow phenomenon of a deposition material passing through the opening.

Accordingly, the deposition quality of a display substrate may be improved.

The effects of the one or more embodiments are not limited to the effects mentioned above, and other effects not mentioned will be clearly understood by those skilled in the art from the description of the claims.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A mask assembly comprising:
a mask frame comprising an opening area;
a body unit disposed such that the body unit covers the mask frame, wherein the body unit comprises ribs that cross the opening area, intersect one another, and define a first opening; and
a mask sheet disposed on a first surface of the body unit and having a sheet unit that defines a plurality of second openings overlapping the first opening,
wherein the sheet unit comprises a first film and a second film, wherein the first film is disposed on the first surface of the body unit, and the second film is disposed on the first film and overlaps the first film, and
a width of the first film between adjacent second openings from among the plurality of second openings is less than a width of the second film between the adjacent second openings.

2. The mask assembly of claim 1, wherein the sheet unit is disposed such that the sheet unit surrounds an outer periphery of the body unit.

3. The mask assembly of claim 1, wherein the first film and the second film are disposed on a second surface of the body unit, the second surface facing the first surface of the body unit.

4. The mask assembly of claim 1, wherein:
the first film comprises silicon oxide, and
the second film comprises silicon nitride.

5. The mask assembly of claim 1, wherein the first film and the second film comprise silicon nitride.

6. The mask assembly of claim 4, wherein the silicon nitride comprises silicon nitride (Si₃N₄).

7. The mask assembly of claim 4, wherein a density of the silicon nitride is about 2.9 g/cm³ to about 3.1 g/cm³.

8. The mask assembly of claim 4, wherein tensile stress of the silicon nitride is about 50 MPa to about 300 MPa.

9. The mask assembly of claim 1, wherein:
the sheet unit further comprises a third film, wherein the third film is disposed on the second film and overlapping the second film, and
the width of the second film between the adjacent second openings is less than a width of the third film between the adjacent second openings.

10. The mask assembly of claim 9, wherein the first film, the second film, and the third film are disposed on a second surface of the body unit, the second surface facing the first surface of the body unit.

11. The mask assembly of claim 9, wherein:
the first film comprises silicon nitride,
the second film comprises silicon oxide, and
the third film comprises silicon nitride.

12. A method of manufacturing a mask assembly, the method comprising:
preparing a body unit, the body unit comprising a silicon material and having a first surface and a second surface facing the first surface;
forming a first film by oxidizing an entire surface of the body unit;
disposing an alignment key on the first film;
forming a second film which surrounds an entire surface of the first film;
etching first portions of the first film and the second film, wherein the first portions are disposed on a second film of the body unit;
forming a first opening by etching the body unit through the second surface of the body unit, wherein the etching exposes the second surface; and
etching second portions of the first film and the second film and forming a plurality of second openings that overlap the first opening, wherein the second portions are exposed through the first opening.

13. The method of claim 12, wherein a width of the first film between adjacent second openings from among the plurality of second openings is less than a width of the second film between the adjacent second openings.

14. The method of claim 12, wherein etching the body unit comprises wet etching the body unit, and the first film functions as a stopper layer to stop the etching.

15. The method of claim 12, wherein the etching of the second portions of the first film and the second film comprises attaching a protective layer onto the second film.

16. The method of claim 12, wherein:
the etching of the second portions of the first film and the second film comprises disposing a photoresist on an inner surface of the first film, and
the inner surface is exposed through the first opening.

17. The method of claim 12, wherein the first portions of the first film and the second film are etched by dry etching.

18. The method of claim 12, wherein the first film comprises silicon oxide and the second film comprises silicon nitride.

19. The method of claim 12, wherein the first film and the second film comprise silicon nitride.

20. A method of manufacturing a mask assembly, the method comprising:
preparing a body unit, the body unit comprising a silicon material and having a first surface and a second surface facing the first surface;
forming a first film which surrounds an entire surface of the body unit;
forming a plurality of first sub-openings by etching part of the first film;
forming a second film by oxidizing an entire surface of the first film, wherein the second film surrounds the entire surface of the first film;
forming a third film which surrounds an entire surface of the second film;
forming a plurality of third sub-openings overlapping the plurality of first sub-openings by etching part of the third film;
etching portions of the first film, the second film, and the third film, wherein the portions of the first film, the second film, and the third film are disposed on the second surface of the body unit;
forming a first opening by etching the body unit through the second surface of the body unit, wherein the etching exposes the second surface, and the second film is exposed through the first opening; and
forming a plurality of second sub-openings overlapping the plurality of first sub-openings by etching the second film exposed through the first opening,
wherein the forming of the plurality of first sub-openings, the plurality of second sub-openings, and the plurality of third sub-openings defines a second opening.
